(19) United States
(12) Patent Application Publication
(10) Pub. No.: US 2026/0334306 A1
(43) Pub. Date: Oct. 22, 2026

(54) MODULAR VERTICAL STACKING OF SEMICONDUCTOR PACKAGES

(71) Applicant: Sandisk Technologies, Inc., Milpitas, CA (US)

(72) Inventors: Yiqin Huang, Shanghai (CN); Cong Zhang, Shanghai (CN)

(73) Assignee: Sandisk Technologies, Inc., Milpitas, CA (US)

(21) Appl. No.: 19/183,054

(22) Filed: Apr. 18, 2025

(51) Int. Cl. H01L 25/00; H01L 21/56; H01L 21/683; H01L 23/00; H01L 25/065; H10B 80/00

(52) U.S. Cl. CPC H10W 90/00; H10B 80/00; H10P 72/7402; H10W 74/016; H10W 70/05; H10W 70/652; H10W 72/01257; H10W 72/01935; H10W 72/0198; H10W 72/952; H10W 80/312; H10W 80/327; H10W 90/297; H10W 90/722; H10W 90/792

(57) ABSTRACT

A semiconductor device having semiconductor package having a vertical stack of memory dies and method for forming the same. The semiconductor package has a stack of modules that each contain a stack of memory dies. Each of the memory dies has TSVs. In an aspect, all but one of the modules has a redistribution structure on one side with micropads or the like in a surface of the redistribution structure. The micropads or the like in the surface of the redistribution structure of a particular module are bonded to microbumps or the like of an adjacent module. The semiconductor package has mold compound that surrounds the stack of modules with microbumps or the like of one of the modules extending out of the mold compound.

### BACKGROUND

The strong growth in demand for portable consumer electronics is driving the need for high-capacity storage devices. Non-volatile semiconductor memory devices, such as flash memory storage cards, are becoming widely used to meet the ever-growing demands on digital information storage and exchange. Their portability, versatility, and rugged design, along with their high reliability and large capacity, have made such memory devices ideal for use in a wide variety of electronic devices, including for example digital cameras, digital music players, video game consoles, PDAs, and cellular telephones.

While many varied packaging configurations are known, flash memory storage cards may in general be fabricated as system-in-a-package (SiP) or multichip modules (MCM), where a plurality of die are mounted and interconnected on a small footprint substrate. The substrate may in general include a rigid, dielectric base having a conductive layer etched on one or both sides. The substrate has electrical connections to provide signals to the memory dies. One technique etches through silicon vias (TSV) into the substrates of the dies to allow for electrical connections to be made between the dies and the substrate. The substrate has an interface to connect to a host to allow the host to control the dies. The stack of dies is typically encased in a mold compound which provides a protective package.

To most efficiently use package footprint it is known to stack semiconductor dies on top of each other. As semiconductor die become thinner, and to increase memory capacity in semiconductor packages, the number of dies stacked within a semiconductor package continues to increase.

It is possible for the dies to warp during the fabrication process. Such die warpage is especially problematic during die to die bonding. Mismatch between the amount of die warpage impairs the formation of the bonds. A “non-wet” condition may result if the die warpage results in too large of a gap between two adjacent dies. A “non-wet” condition may result in a failure for bonds to form between two adjacent dies. An “over-collapse” condition may result if the die warpage results in too small of a gap between two adjacent dies. An over-collapse condition may result in improperly formed bonds. Therefore, die warpage can lead to yield loss. Signal integrity may also be impaired if the bonds are not well-formed.

Die warp becomes a greater problem with thinner dies. Moreover, as the die stack gets higher the cumulative effect of die warpage becomes greater. The yield loss can increase substantially as more dies are added to the stack.

### BRIEF DESCRIPTION OF THE DRAWINGS

Like-numbered elements refer to common components in the different figures.

FIG. 1A depicts an embodiment of a semiconductor package having a large number of dies in a stack.

FIG. 1B depicts another embodiment of a semiconductor package having a large number of dies in a stack.

FIG. 1C depicts a table that summarizes a number of embodiments of fabricating a semiconductor package having separately fabricated modules.

FIG. 2 is a flowchart of an embodiment of fabricating a semiconductor package having separately fabricated modules.

FIGS. 3A, 3B, 3C, and 3D depicts results after step 202 of embodiments of the process of FIG. 2.

FIGS. 4A and 4B depicts results after step 210 of embodiments of the process of FIG. 2.

FIGS. 5A, 5B, and 5C depicts results after step 212 of embodiments of the process of FIG. 2.

FIGS. 6A, 6B, and 6C depicts results after step 216 of embodiments of the process of FIG. 2 having chip-on-chip on carrier (CoCoC).

FIGS. 7A, 7B, and 7C depicts results after step 218 of embodiments of the process of FIG. 2.

FIGS. 8A, 8B, and 8C depicts results after step 220 of embodiments of the process of FIG. 2.

FIGS. 9A and 9B depicts results after step 222 of embodiments of the process of FIG. 2.

FIGS. 10A and 10B depicts results after step 224 of embodiments of the process of FIG. 2.

FIGS. 11A and 11B depicts results after step 226 of embodiments of the process of FIG. 2.

FIGS. 12A and 12B depicts results after step 228 of embodiments of the process of FIG. 2.

FIGS. 13A, 13B, and 13C depicts results after step 230 of embodiments of the process of FIG. 2 that have a module on module on carrier.

FIG. 13D depicts results after step 230 of an embodiment of the process of FIG. 2 that have a module on module on reconstructed wafer.

FIG. 14A depicts results after step 232 of embodiments of the process of FIG. 2 that have a module on module on carrier.

FIG. 14B depicts results after step 232 of embodiments of the process of FIG. 2 that have a module on module on reconstructed wafer.

FIG. 15A depicts results after step 234 of embodiments of the process of FIG. 2 that have a module on module on carrier.

FIG. 15B depicts results after step 234 of embodiments of the process of FIG. 2 that have a module on module on reconstructed wafer.

FIGS. 16A and 16B results after step 216 of embodiments of the process of FIG. 2 having chip on chip on core wafer (CoCoW).

FIGS. 17A and 17B results after step 218 of embodiments of the process of FIG. 2.

FIG. 18 depicts results after step 228 of embodiments of the process of FIG. 2.

FIGS. 19A and 19B results after step 230 of embodiments of the process of FIG. 2.

FIG. 20A depicts results after step 232 of embodiments of the process of FIG. 2 that have a module on module on carrier.

FIG. 20B depicts results after step 232 of embodiments of the process of FIG. 2 that have a module on module on reconstructed wafer.

FIG. 21A depicts results after step 234 of embodiments of the process of FIG. 2 that have a module on module on carrier.

FIG. 21B depicts results after step 234 of embodiments of the process of FIG. 2 that have a module on module on reconstructed wafer.

FIGS. 22A and 22B depict results after embodiments of step 204 of FIG. 2 that uses hybrid bonding.

FIGS. 23A and 23B depict results after embodiments of step 212 of FIG. 2 that uses hybrid bonding.

FIGS. 24A, 24B, and 24C depict results after embodiments of step 214 of FIG. 2 that uses hybrid bonding.

FIGS. 25A, 25B, and 25C depict results after embodiments of step 216 of FIG. 2 that uses hybrid bonding.

FIGS. 26A, 26B, and 26C depict results after embodiments of step 218 of FIG. 2 that uses hybrid bonding.

FIGS. 27A and 27B depict results after embodiments of step 228 of FIG. 2 that uses hybrid bonding.

FIGS. 28A, 28B, and 28C depict results after embodiments of step 230 of FIG. 2 that uses hybrid bonding.

FIGS. 29A, 29B, and 29C depict results of forming a semiconductor package that uses hybrid bonding in a module on module on carrier embodiment.

FIGS. 30A, 30B, and 30C depict results of forming a semiconductor package that uses hybrid bonding in a module on module on reconstructed wafer embodiment.

FIGS. 31A and 31B depict results of forming a semiconductor package that uses hybrid bonding in a reconstructed wafer on reconstructed wafer embodiment.

### DETAILED DESCRIPTION

The present technology will now be described with reference to the figures, which in embodiments, relate to a semiconductor package having a vertical stack of memory dies and method for forming the same. The semiconductor package has a stack of modules that each contain a stack of memory dies. Most of the memory dies have TSVs. In an embodiment, all but one of the modules has a redistribution structure on one side with micropads or the like in a surface of the redistribution structure. The micropads or the like in the surface of the redistribution structure of a particular module are bonded to microbumps or the like of an adjacent module. The semiconductor package has mold compound that surrounds the stack of modules with microbumps or the like of one of the modules extending out of the mold compound. Therefore, the semiconductor package has a very large stack of memory dies. Also, the bonds are well-formed thereby resulting in good signal transfer through the bonds. In an embodiment, copper-copper hybrid bonding is used between micropads of adjacent modules in the semiconductor package. The copper-copper hybrid may also be referred to as copper/dielectric hybrid bonding.

An embodiment includes a method of fabricating a semiconductor package having a vertical stack of memory dies. The method includes forming a number of modules with each module having a stack of memory dies. At least a subset of the memory dies in each of the modules have through silicon vias (TSVs). The method includes forming first microcontacts (e.g., microbumps, first copper micropads) that are conductively connected to the TSVs of a bottom die of each of the modules. The method includes forming a stack of memory dies for each module. The method includes revealing the TSVs of a top memory die of the stack for all but one of the modules. The method includes forming second microcontacts (e.g. micropads, second copper micropads) that are conductively connected to the revealed TSVs of the top memory die of the particular module. The method includes stacking the modules vertically with the second microcontacts of the top die of all but one of the modules aligned with the first microcontacts of the bottom die of an adjacent module. The method includes bonding the first microcontacts that are aligned with the second microcontacts. In one embodiment, microbumps of one module are bonded to micropads of another module. In one embodiment, the first copper micropads of one module are bonded to the second copper micropads of another module by Cu—Cu hybrid bonding. Because the individually formed modules have smaller die stacks issues of die warpage are substantially reduced. Therefore, yield improves. Also, thinner memory dies may be used within the modules, which reduces the height of the die stack.

It is understood that the present technology may be embodied in many different forms and should not be construed as being limited to the embodiments set forth herein. Rather, these embodiments are provided so that this disclosure will be thorough and complete and will fully convey the technology to those skilled in the art. Indeed, the technology is intended to cover alternatives, modifications, and equivalents of these embodiments, which are included within the scope and spirit of the technology as defined by the appended claims. Furthermore, in the following detailed description of the present technology, numerous specific details are set forth in order to provide a thorough understanding of the present technology. However, it will be clear to those of ordinary skill in the art that the present technology may be practiced without such specific details.

The terms “top” and “bottom,” “upper” and “lower,” and “vertical” and “horizontal” as may be used herein are by way of example and illustrative purposes only, and are not meant to limit the description of the technology inasmuch as the referenced item can be exchanged in position and orientation. Also, as used herein, the terms “substantially,” “approximately” and/or “about” mean that the specified dimension or parameter may be varied within an acceptable manufacturing tolerance for a given application. In one embodiment, the acceptable manufacturing tolerance is ±0.25%.

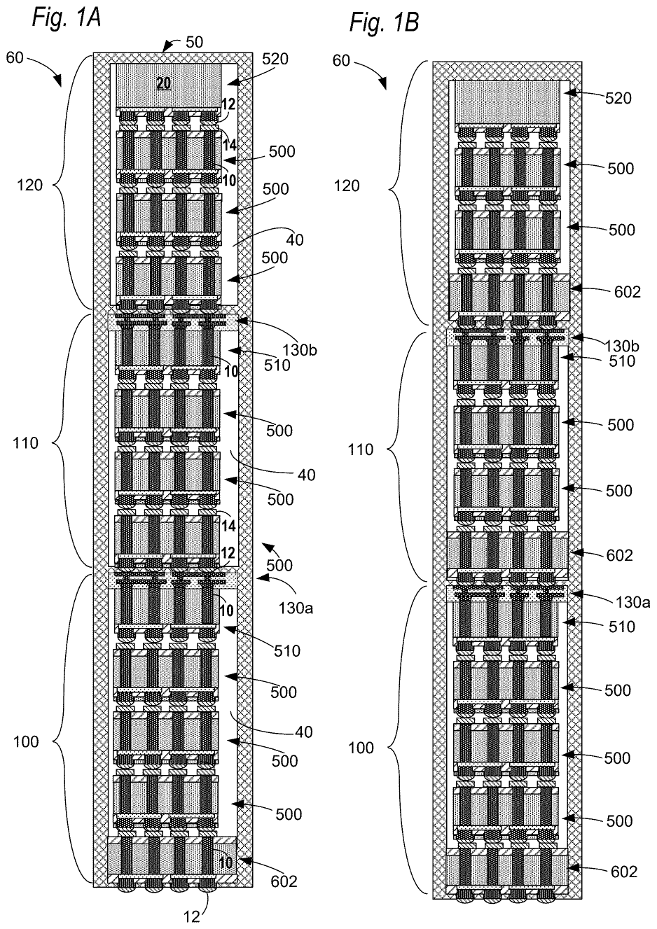

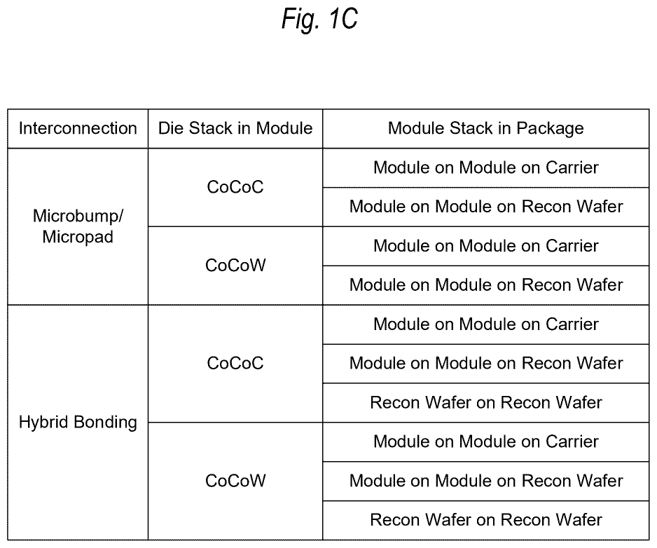

FIG. 1A depicts an embodiment of a semiconductor package having a large number of dies in a stack. The semiconductor package is divided into three separate modules 100, 110, 120. Each module 100, 110, 120 could also be referred to as a “package” or a “cube.” Two of the modules include RDL structures 130, which are used to bond the modules together. Module 100 has a first RDL structure 130a and module 110 has a second RDL structure 130b. The package 60 has a first mold compound 50 that fills a small gap between the modules and also surrounds the sides of the modules. For the sake of discussion the modules will be referred to as a bottom module 100, a middle module 110, and a top module 120 based on their relative positions to a substrate upon which the modules are stacked during the fabrication process.

Each module has a stack of dies. In an embodiment, at least some of the dies contains memory cells such as Flash memory (e.g., NAND, NOR). Such dies that contain accessible memory cells are referred to herein as “memory dies.” The dies have significant differences, wherein different reference numerals will be used to refer to the dies. In an embodiment, each die is referred to as either a core die 602, TSV bump/pad die 500, RDL die 510, or a TSV free die 520. In an embodiment, the TSV bump/pad die 500, RDL die 510, and TSV free die 520 each contain memory cells and may be referred to as memory dies. In an embodiment, the core die 602 includes a memory controller that controls access to the memory cells in the memory dies.

The bottom module 100 has a stack of five memory dies in this example. The core die 602 has through silicon vias (TSVs) 10 with a microbump 12 for each TSV. The microbumps 12 on this core die 602 are accessible from outside of the package 60 such that the package 60 may be bonded to a substrate, interposer, or the like. The bottom module 100 also has three of the TSV bump/pad dies 500. Each TSV bump/pad die has TSVs 10, microbumps 12 on one side of the die and micropads 14 on the other side of the die. Within the bottom module 100 the microbumps 12 are bonded to the micropads 14. The RDL die 510 is so-named because it is adjacent to the RDL structure 130a. Note, however, that the RDL structure 130a is not a physical part of the RDL die 510. As will be explained below, the RDL structure 130a is formed on the RDL die 510 during an embodiment of a fabrication process. The memory dies in the bottom module are encapsulated with a second mold compound 40.

The middle module 110 has a stack of four memory dies in this example. The middle module 110 has three of the TSV bump/pad dies 500 and an RDL die 510. The TSV bump/pad dies 500 may be similar to the TSV bump/pad dies 500 in the bottom module 100. Thus, each TSV bump/pad die of the middle module 110 has TSVs 10, microbumps 12 on one side of the die and micropads 14 on the other side of the die. Within the middle module 110 the microbumps 12 are bonded to the micropads 14. The memory dies in the middle module 110 are encapsulated with the second mold compound 40.

The top module 120 has a stack of four memory dies in this example. The top module 120 has three of the TSV bump/pad dies 500 and a TSV free die 520. The TSV bump/pad dies 500 may be similar to the TSV bump/pad dies 500 in the bottom module 100 and the middle module 110. Thus, each TSV bump/pad die of the top module 120 has TSVs 10, microbumps 12 on one side of the die and micropads 14 on the other side of the die. The top module 120 has a TSV free die 520 that does not require TSVs due to its location. However, the TSV free die 520 has microbumps 12 to bond to micropads 14 of the adjacent memory die. Thus, within the top module 120 the microbumps 12 are bonded to the micropads 14. The memory dies in the top module 120 are encapsulated with the second mold compound 40.

As noted above bottom module 100 has an RDL structure 130a. The RDL structure 130a serves as an interface between the RDL die 510 in the bottom module 100 and the adjacent TSV bump/pad dies 500 in the middle module 110. The microbumps 12 on the adjacent TSV bump/pad dies 500 in the middle module 110 are bonded to micropads or the like on the RDL structure 130a of the bottom module 100. As noted above, the middle module 110 has an RDL structure 130b. The RDL structure 130b serves as an interface between the RDL die 510 in the middle module 110 and the adjacent TSV bump/pad dies 500 in the top module 120. The microbumps 12 on the adjacent TSV bump/pad dies 500 in the top module 120 are bonded to micropads or the like on the RDL structure 130b of the middle module 110.

FIG. 1B depicts another embodiment of a semiconductor package having a large number of dies in a stack. The package is similar to the one in FIG. 1A. However, middle module 110 and the top module 120 in FIG. 1B each have a core die 602 with a larger die size than dies 500.

Fabricating semiconductor packages with a high number of dies in a stack such as the semiconductor devices depicted in FIGS. 1A and 1B is very challenging due issues such as die warpage. Fabricating the modules 100, 110, 120 separately allows for smaller die stacks to be formed to thereby alleviate die warpage issues when forming die stacks with a larger number of dies.

FIGS. 1A and 1B depict two embodiments of many embodiments of a semiconductor package having multiple modules, with each module having a stack of memory dies. In some embodiments, the RDL structure 130 is not present between the modules in the semiconductor package. In some embodiments, Cu-Cu hybrid bonding is used between the modules in the semiconductor package.

A number of embodiments are disclosed for fabricating a semiconductor package from multiple modules. FIG. 1C depicts a table that summarizes a number of embodiments. However, fabricating the semiconductor package from multiple modules is not limited to the embodiments in the table. The table lists two techniques for the connections between the modules. In some embodiments, the interconnections between two modules are made with microbumps of one module and micropads of the adjacent module (Microbump/Micropads). In some embodiments, the interconnections between two modules are made with hybrid bonding (e.g., Cu—Cu hybrid bonding). The table lists two techniques for forming the stack of dies within a module. In some embodiments, the die stacks within a module are fabricated using Chip-on-Chip on a temporary carrier (CoCoC). In some embodiments, the die stacks within a module are fabricated using Chip-on-Chip on core Wafer (CoCoW). Each technique (CoCoC, CoCoW) may be used with either Microbump/Micropads or with hybrid bonding. The table lists three techniques for fabricating the modules in the semiconductor package. A module on module on carrier technique may be used with Microbump/Micropads or with hybrid bonding. A module on module on reconstructed (recon) wafer technique may be used with Microbump/Micropads or with hybrid bonding. Additionally, a recon wafer on recon wafer technique may be used with hybrid bonding.

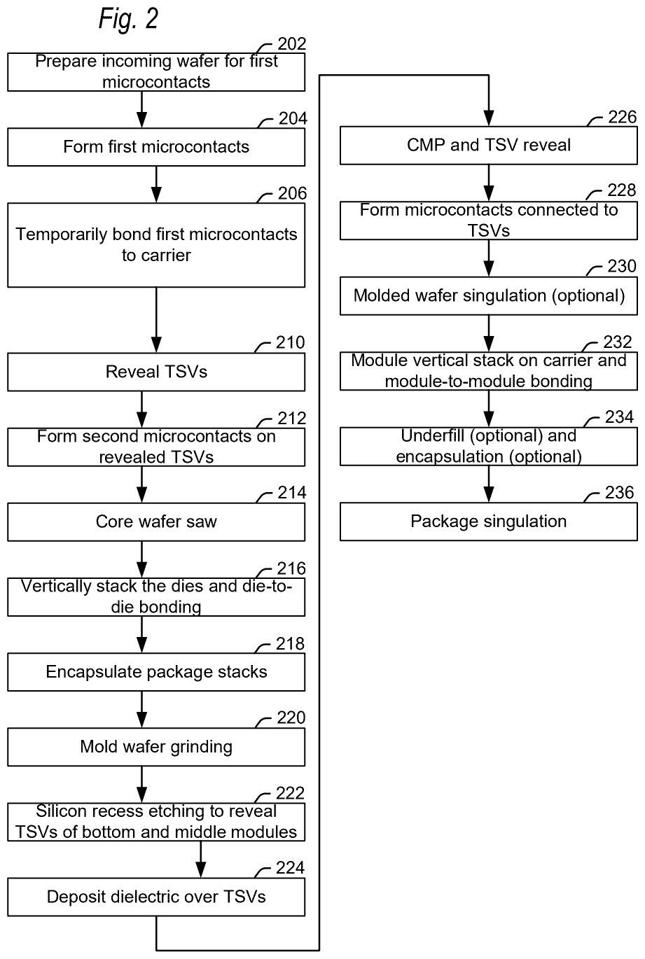

FIG. 2 is a flowchart of an embodiment of fabricating a semiconductor package having separately fabricated modules. The process involves fabricating modules, with each module having a stack of memory dies. Then, the modules are bonded together and may be encapsulated to form the final package. The process in FIG. 2 may be used with any the techniques described in FIG. 1C, but is not limited to these techniques. For ease of discussion, the process will first be described with respect to CoCoC with Microbumps. Then, the process will be described with respect to CoCoW with Microbumps. Finally, the process will be described with respect to hybrid bonding.

In an embodiment, the vertical stacking of the memory dies for the middle module and the top module is on a temporary carrier. This temporary carrier embodiment may be used to form a package such as in FIG. 1A. In an alternative embodiment, the memory dies of the middle module and the top module are each stacked on core wafers. This core wafer embodiment may be used to form a package such as in FIG. 1B. For ease of discission the process of FIG. 2 will first be described with respect to a temporary carrier embodiment. Then, the process of FIG. 2 will be described with respect to a core wafer embodiment. The process of FIG. 2 will be described with respect to embodiments in which there are three modules. However, there could be more or fewer than three modules. Also, the number of semiconductor dies per module may be increased or decreased from the examples in the Figures herein.

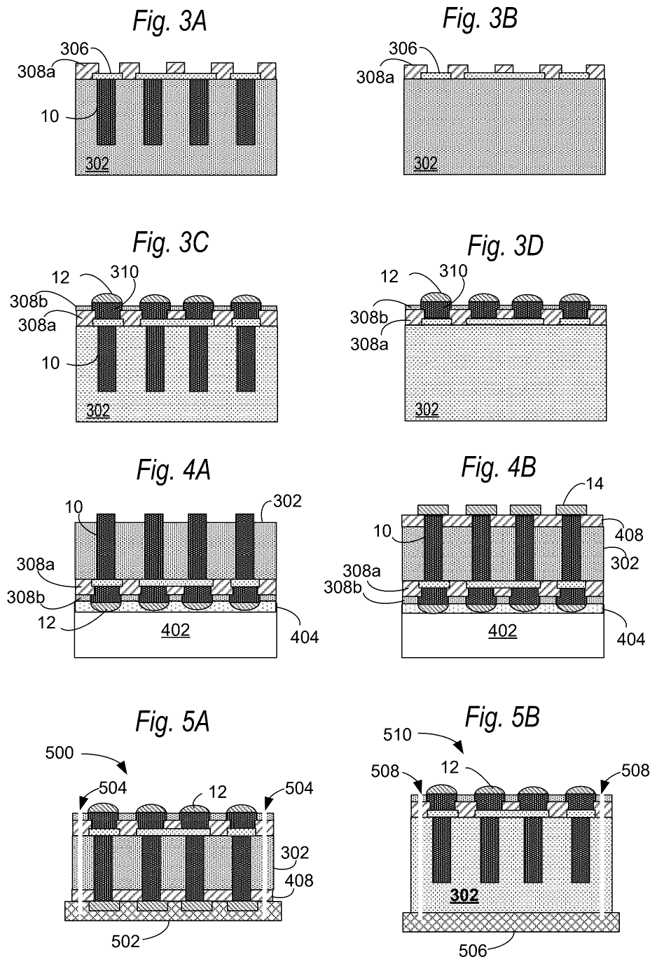

Step 202 includes preparing an incoming wafer for first microcontacts. In an embodiment, an incoming wafer is prepared for microbumping. In an alternative embodiment, an incoming wafer is prepared for hybrid bonding. The incoming wafer may already have through silicon vias (TSV) 10 in semiconductor substates. However, the TSVs are not needed for what is to become the topmost semiconductor die in the top module 120. Step 202 may include forming metal pads on the surface of each semiconductor substate. Step 202 may also include forming a passivation layer on the semiconductor substates to partially cover the metal pads. FIG. 3A shows results after an embodiment of step 202 in which TSVs 10 are formed in the semiconductor substrate 302. FIG. 3A shows results that may be used for all semiconductor dies in the bottom modules 100 and middle modules 110, as well as all semiconductor dies of the top module 120 with the exception of the top semiconductor die. FIG. 3A depicts in incoming wafer 302 with through silicon vias (TSV) 10 in the silicon wafer 302. Metal interconnects 306 are depicted. The metal interconnects 306 connect to the TSVs 10 and to electronic devices such as transistors (not depicted in FIG. 3A). A passivation layer 308a is formed to cover edge portions of metal interconnects 306. The metal interconnects 306 may be formed from materials including, but not limited to, aluminum, copper, silver, gold, nickel, tungsten, alloys thereof, and/or multi-layers thereof. The passivation layer 308a may be formed of a dielectric material. The depiction of the metal interconnects 306 is simplified in that there may be multiple layers of metal interconnects that may be formed in, for example, a back end of line (BEOL) process. The side of the die having the metal interconnects 306 in FIG. 3A may also have devices such as memory cells and transistors (e.g., CMOS), which may be formed in a front end of line process. FIG. 3B shows results after an embodiment of step 202 in which TSVs are not formed in the semiconductor substrate 302. FIG. 3B shows results that may be used for the topmost semiconductor dies (see die 520 in FIGS. 1A, 1B) in the top module 120. FIG. 3B depicts the metal interconnects 306 and passivation layer 308. There may also be devices such as memory cells and transistors on the side of the die having the metal interconnects 306.

Step 204 includes forming first microcontacts. In an embodiment, step 204 includes microbump bumping. A photoresist may be used as a pattern for the microbumps. Copper may be formed over the metal pads 306 within the pattern defined by the photoresist. In one embodiment a UBM (under bump metallization) layer is deposited on the metal pads 306 prior to forming the copper. Metal (e.g., Sn/Ag) for the microbumps may be placed over the copper. Reflow may be used to form the final shape of the microbumps. FIG. 3C results after an embodiment of step 204 that may be used for all semiconductor dies in the bottom modules 100 and middle modules 110, as well as all semiconductor dies of the top module 120 with the exception of the top semiconductor die. FIG. 3C shows a copper layer 310 has been formed over the metal pads 306 in region within the passivation layers 308a, 308b. The passivation layers 308a, 308b are depicted as two layers, which may be different materials such as, SiO2 and SiN. The passivation layers 308a, 308b may have different thicknesses. Microbumps 12 are formed on the copper layer 310. Not all layers are depicted in FIG. 3C. For example, the UBM layer between the metal pads 306 and copper 310 is not depicted. Also, there may be one or more diffusion barrier layers and one or more seed layers, which are not depicted in the Figures. FIG. 3D shows results after an embodiment of step 204 that may be used for the topmost semiconductor dies in the top module 120. FIG. 3D is similar to FIG. 3C, but lacks the TSVs. The side in which the micropads 14 are formed may be referred to as the “device side” of the die due to presence of devices such as, for example, memory cells, transistors, etc.

Step 206 includes temporarily bonding the first microcontacts to a carrier. In an embodiment, an adhesion film is formed over the first microcontacts (e.g., microbumps 12) to wrap them well. Also, a release film is formed over a temporary carrier. The release film allows the wafer to easily be removed from the carrier later in the process. Step 210 includes revealing the TSVs. FIG. 4A depicts results after an embodiment of step 210 for all but the topmost dies of each module. A temporary film 404 covers the microbumps 12. The temporary film 404 represents both the adhesion film and the release film. The TSVs 10 have been revealed in the semiconductor substrate 302. The side in which the TSVs are revealed may be referred to as the “silicon side” or the “back side” of the die.

Step 212 includes forming second microcontacts on the revealed TSVs. In an embodiment, the second microcontacts include micropads. FIG. 4B depicts results after an embodiment of step 212 for all but the topmost dies of each module. FIG. 4B shows micropads 14 have been formed over the revealed TSVs 10 in a region within a passivation 408. The passivation 408 may contain more than one layer. For example, passivation 408 may contain a layer of SiO2 and a layer of SiN, which may have different thicknesses. In an embodiment, the micropads 14 are formed from nickel with a thin gold layer. Copper or gold may also be used for the micropads 14. There may be additional layers not depicted in the drawings. In an embodiment, there is a titanium barrier layer (not depicted in FIG. 4B) between the TSV 10 and the micropad 14.

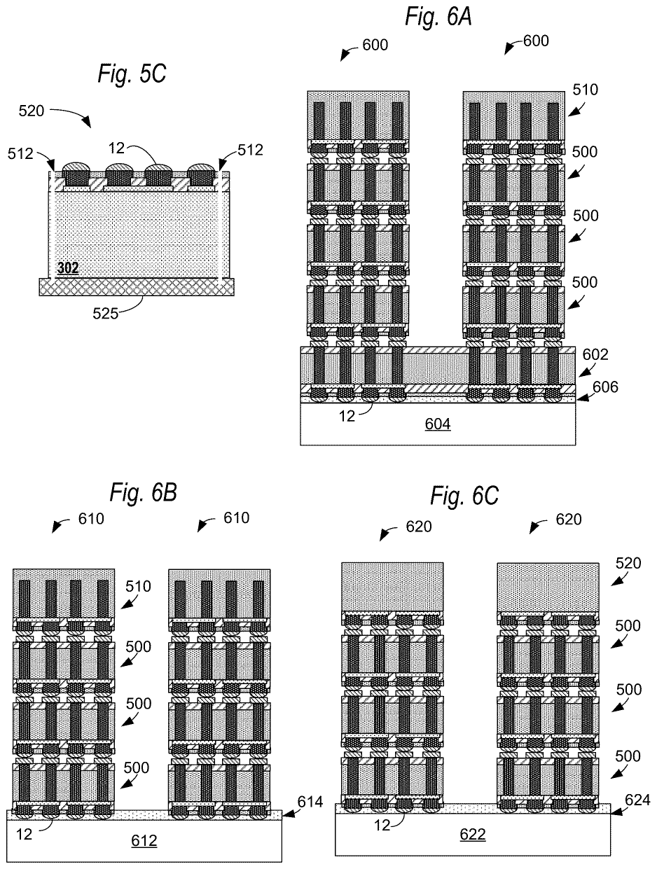

Step 214 includes a core wafer saw. FIG. 5A depicts results after an embodiment of step 212 for all but the topmost dies of each module. FIG. 5A depicts a semiconductor die 500 with a tape 502 is attached to the passivation layer 408 and micropads 14. Open region 504 indicates where the core wafer saw has been used to dice the wafer into semiconductor die 500. FIG. 5B depicts results after an embodiment of step 212 for the RDL dies 510 of the bottom and middle modules. The RDL dies 510 of the bottom and middle modules do not have micropads 14 attached to the TSV 10. A tape 506 is attached to the substrate 302. Open region 508 indicates the core wafer saw has been used to dice the wafer into semiconductor die 510. FIG. 5C depicts results after an embodiment of step 212 for the topmost dies 520 of the top module, which does not have TSVs. A tape 525 is attached to the substrate 302. Open region 512 indicates the core wafer saw has been used to dice the wafer into semiconductor die 520.

Step 216 includes vertically stacking the semiconductor dies to form modules. Step 216 also includes die-to-die bonding. The die-to-die bonding could include, for example, thermal compression bonding, tacking and mass reflow, laser assisted bonding, or laser compression bonding. In an embodiment, step 216 includes bonding microbumps of one memory die to micropads of another memory die. In an embodiment, a bottom module, a middle module, and a top module are formed. In an embodiment, the bottom module is formed on a base wafer, whereas the middle module and the top module are formed on temporary carriers. FIG. 6A depicts an embodiment of two stacks 600 formed on the same core wafer 602. The stacks 600 will bottom modules 100. Each stack 600 has three TSV bump/pad die 500 and an RDL die 510 at the top. The core wafer 602 has TSVs, metal pads, and microbumps similar to TSV bump/pad die 500. The core wafer 602 resides on a temporary carrier 604, with a temporary film 606 between the core wafer 602 and temporary carrier 604. The temporary may include an adhesion film that wraps and fixes the microbumps 12 as well as a release film. The temporary film 606 should be thick enough to cover the microbumps 12. The temporary film 606 should be able to endure a high temperature (e.g., 175 degrees Celsius) of the stacking and molding used to form the modules. In an embodiment, the temporary film 606 has a low modulus.

The stacks 610 will middle modules 110. FIG. 6B depicts an embodiment of two stacks 610 formed on the temporary carrier 612. Each stack 610 has three TSV bump/pad die 500 and an RDL die 510 at the top. A temporary film 614 is attached to the microbumps of the bottommost TSV bump/pad die 500. FIG. 6C depicts an embodiment of two stacks 620 formed on the temporary carrier 622. The stacks 620 will become top modules 120. Each stack 620 has three TSV bump/pad dies 500 and a TSV free die 520 at the top. A temporary film 624 may include an adhesion film attached to the microbumps 12 of the bottommost TSV bump/pad die 500, as well as a release film.

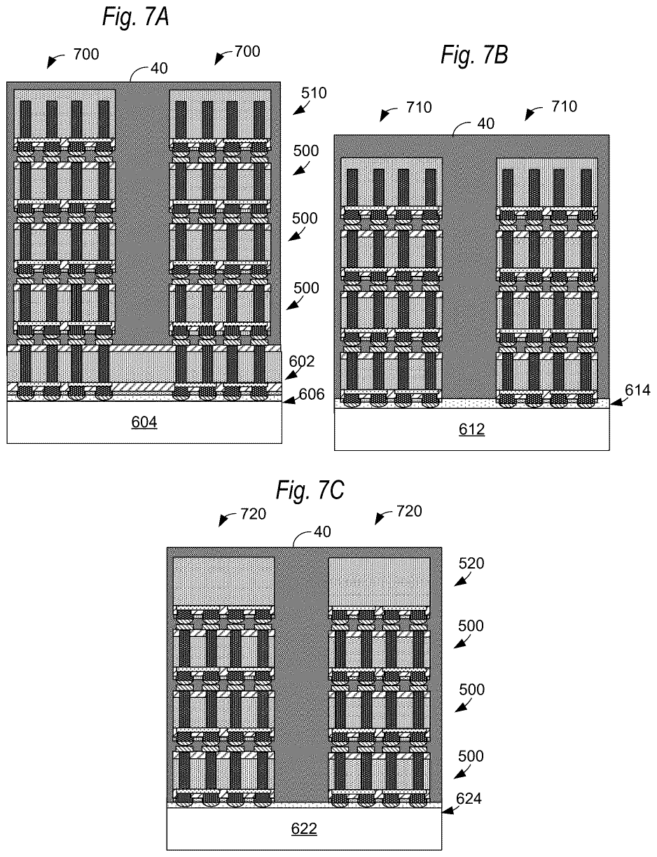

Step 218 includes encapsulating the package stacks with a mold compound. FIGS. 7A, 7B, and 7C correspond to FIGS. 6A, 6B and 6C, respectively, and depict results after embodiments of step 218. FIG. 7A depicts a mold compound 40 encapsulating the two stacks 700 that will become bottom modules 100. FIG. 7B depicts a mold compound 40 encapsulating the two stacks 710 that will become middle modules 110. FIG. 7C depicts a mold compound 40 encapsulating the two stacks 720 that will become top modules 120.

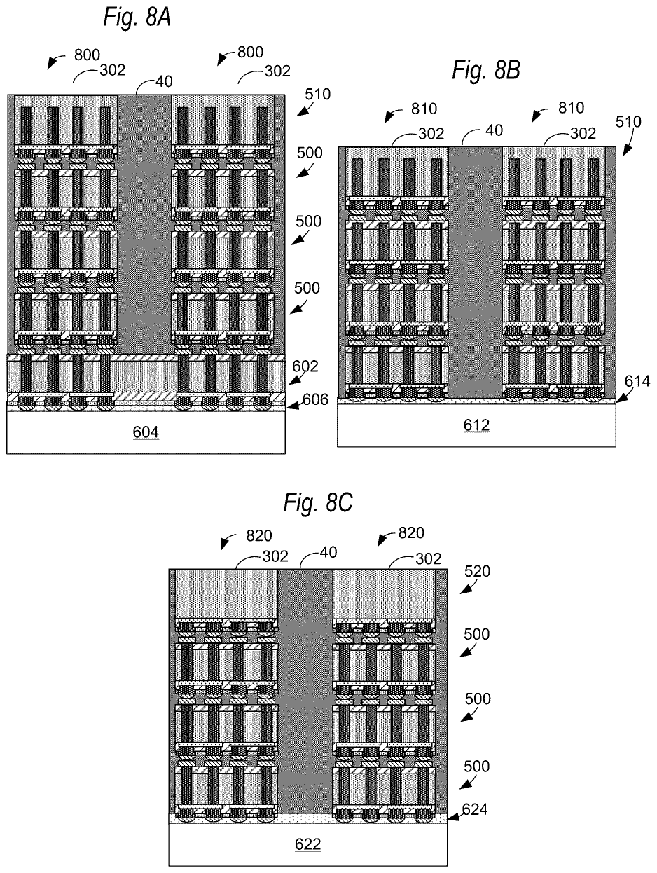

Step 220 includes mold wafer grinding. FIGS. 8A, 8B, and 8C correspond to FIGS. 7A, 7B and 7C, respectively, and depict results after embodiments of step 220. FIG. 8A depicts results with mold compound 40 having been ground down to the level of the substrate 302 of the RDL die 510 in the two stacks 800 that will become bottom modules 100. FIG. 8B depicts results with mold compound 40 having been ground down to the level of the substrate 302 of the RDL die 510 in the two stacks 810 that will become middle modules 110. FIG. 8C depicts results with mold compound 40 having been ground down to the level of the substrate 302 of the TSV free die 520 of in the two stacks 820 that will become top modules 120.

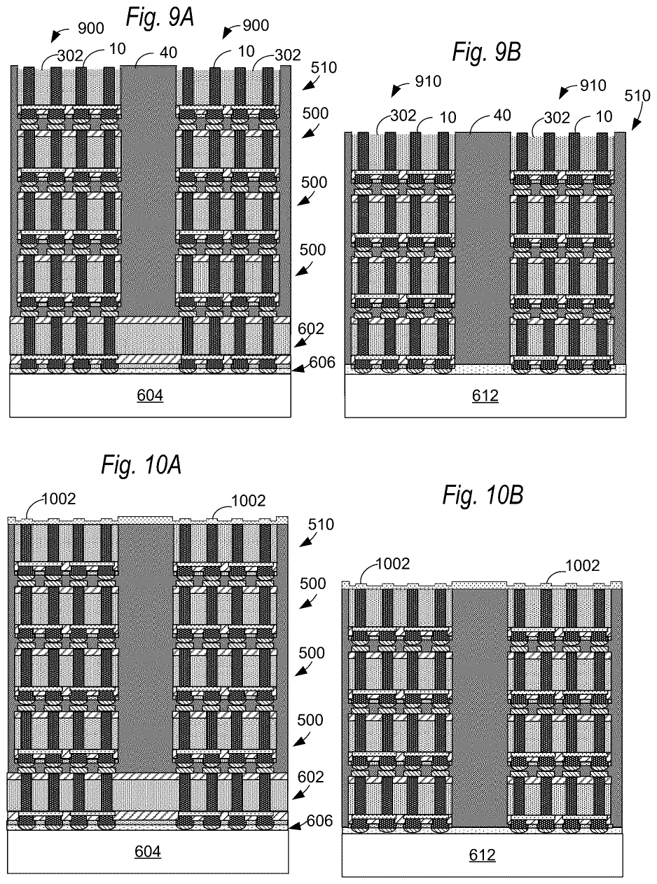

Step 222 includes silicon recess etching for the bottom modules 100 and the middle modules 110. FIGS. 9A and 9B correspond to FIGS. 8A and 8B, respectively, and depict results after embodiments of step 222. FIG. 9A shows the silicon substrate 302 of RDL die 510 in stacks 900 that will become bottom modules 100 having been etched back to reveal the TSVs 10. FIG. 9B also shows the silicon substrate 302 of RDL die 510 in stacks 910 that will become middle modules 110 having been etched back to reveal the TSVs 10. Note that the silicon recess etching of step 222 is performed while the memory dies are in a vertical stack. Also, in FIG. 9A the vertical stacks are the temporary carrier 604 with the temporary film 606 over the microbumps. Also, in FIG. 9B the vertical stacks are the temporary carrier 612 with the temporary film 606 over the microbumps.

Step 224 includes depositing a dielectric over the exposed TSVs for the bottom modules 100 and the middle modules 110. FIGS. 10A and 10B correspond to FIGS. 9A and 9B, respectively, and depict results after embodiments of step 224. FIG. 10A shows the dielectric 1002 over the TSVs 10, as well as over the substrate 302 of the RDL die 510. FIG. 10B also shows the dielectric 1002 over the TSVs 10, as well as over the substrate 302 of the RDL die 510.

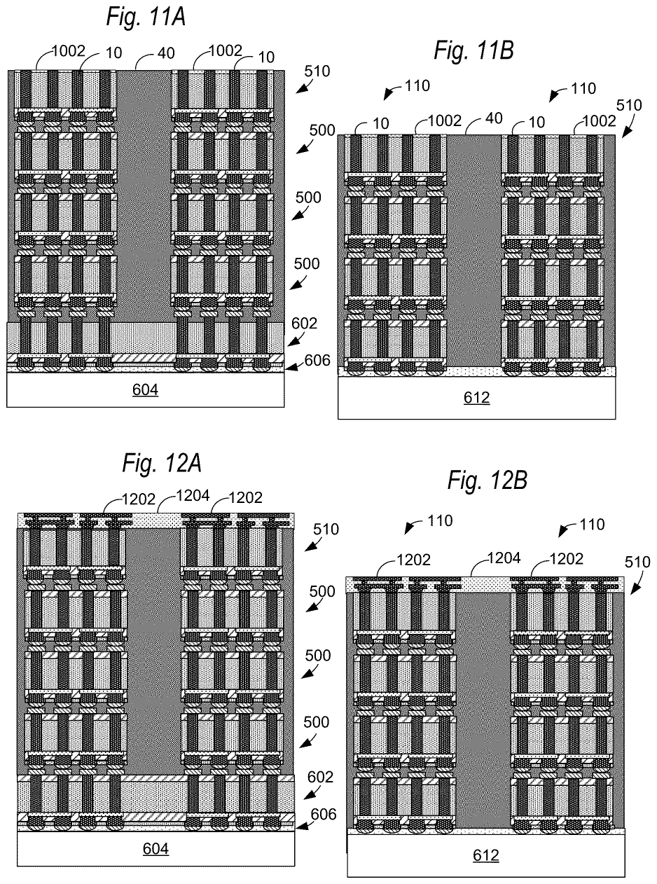

Step 226 includes a chemical mechanical polish (CMP) and TSV reveal for the bottom modules 100 and the middle modules 110. FIGS. 11A and 11B correspond to FIGS. 10A and 10B, respectively, and depict results after embodiments of step 226. FIG. 11A shows that TSVs 10 of the RDL die 510 are revealed, with portions of the dielectric 1002 remaining over the substrate 302. FIG. 11B also shows that TSVs 10 of the RDL die 510 are revealed, with portions of the dielectric 1002 remaining over the substrate 302.

Step 228 includes forming microcontacts that connect to TSVs for the bottom modules 100 and the middle modules 110. In an embodiment, step 228 includes RDL and micropad fabrication for the bottom modules 100 and the middle modules 110. FIGS. 12A and 12B correspond to FIGS. 11A and 11B, respectively, and depict results after embodiments of step 228. FIG. 12A shows micropads 1202 within a dielectric material 1204. FIG. 12A shows other RDL layers within the dielectric material 1204. The dielectric material 1204 may be formed from one or more layers of dielectric material 1204. One or more types dielectrics may be used for dielectric material 1204. FIG. 12B also shows micropads 1202 within a dielectric material 1204 that contains other RDL layers.

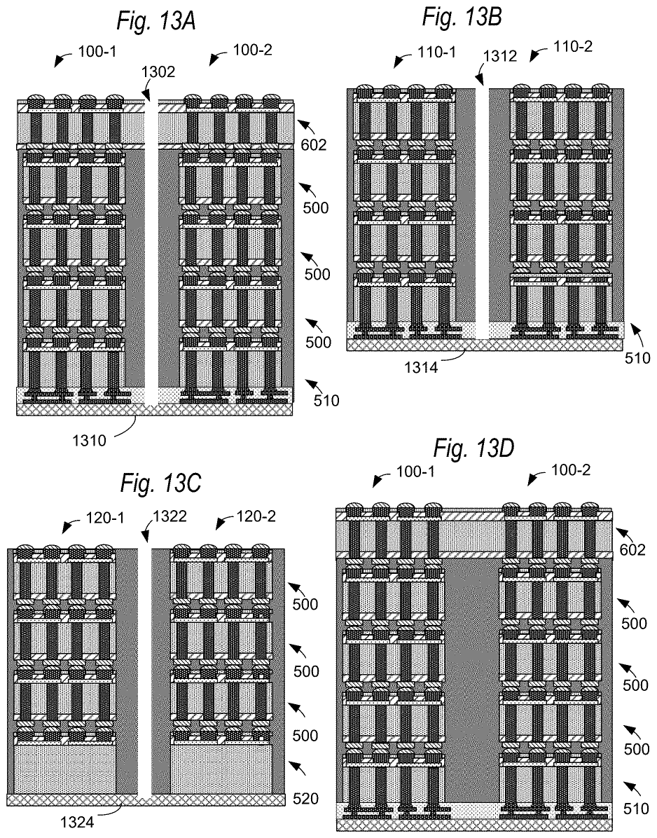

Step 230 includes wafer singulation. In one embodiment, wafer singulation is performed for the bottom modules 100, middle modules 110, and top modules 120. In one embodiment, wafer singulation is performed for the middle modules 110 and top modules 120; however, wafer singulation is not performed for the bottom modules 100. FIGS. 13A, 13B, 13C depict results after embodiments of step 230 in which wafer singulation is performed for bottom modules 100, middle modules 110, and top modules 120, respectively. FIG. 13A corresponds to results after wafer singulation of the stacks in FIG. 12A. FIG. 13A depicts bottom modules 100-1, 100-2 which result from the wafer cut 1302. The bottom modules 100-1, 100-2 are on a die attach tape 1310. FIG. 13B corresponds to results after wafer singulation of the stacks in FIG. 12B. FIG. 13B depicts middle modules 110-1, 110-2 which result from the wafer cut 1312. The middle modules 110-1, 110-2 are on a die attach tape 1314. FIG. 13C depicts top modules 120-1, 120-2 which result from the wafer cut 1322. The top modules 120-1, 120-2 are on a die attach tape 1324. FIG. 13C corresponds to wafer singulation of the top modules 120 in FIG. 8C. FIG. 13D depicts results for an embodiment in which wafer singulation is not performed for the bottom modules 100.

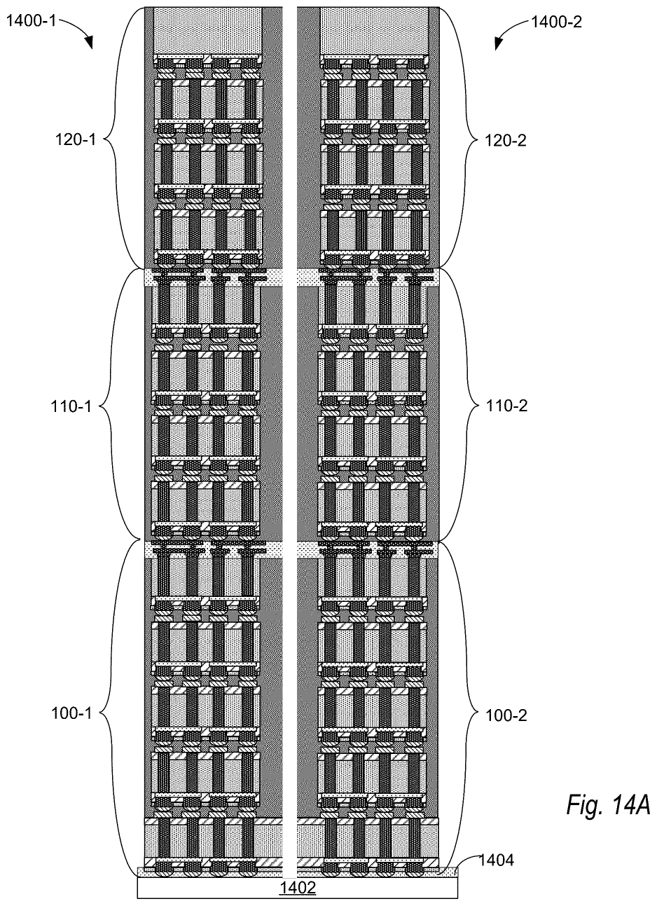

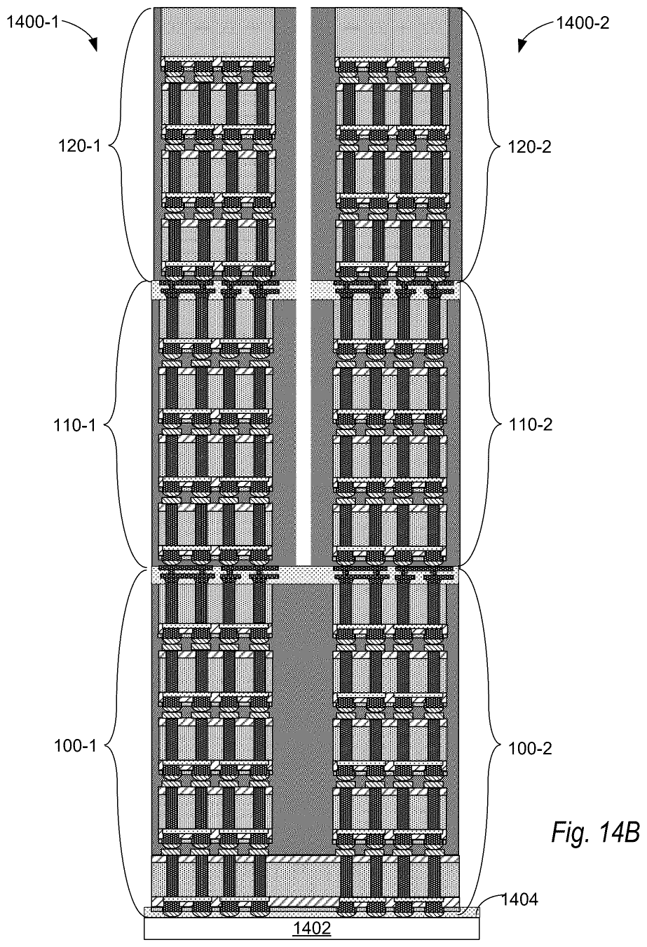

Step 232 includes stacking the modules vertically on a carrier. Step 232 includes bonding the modules together. The module-to-module bonding could include, for example, thermal compression bonding, tacking and mass reflow, laser assisted bonding, or laser compression bonding. In an embodiment, step 232 includes bonding microbumps of one module to micropads of another module. FIG. 14A depicts results after an embodiment of step 232 in which all modules underwent wafer singulation. Bottom module 100-1, middle module 110-1, and top module 120-1 are stacked vertically in a first stack 1400-1 over a carrier 1402, which is attached to the stack by a film 1404. Bottom module 100-2, middle module 110-2, and top module 120-2 are stacked vertically in a second stack 1400-2 over the carrier 1402. FIG. 14B depicts results after an embodiment of step 232 in which the middle modules 110 and top modules 120 underwent wafer singulation, but the wafer singulation was not performed for the bottom modules 100.

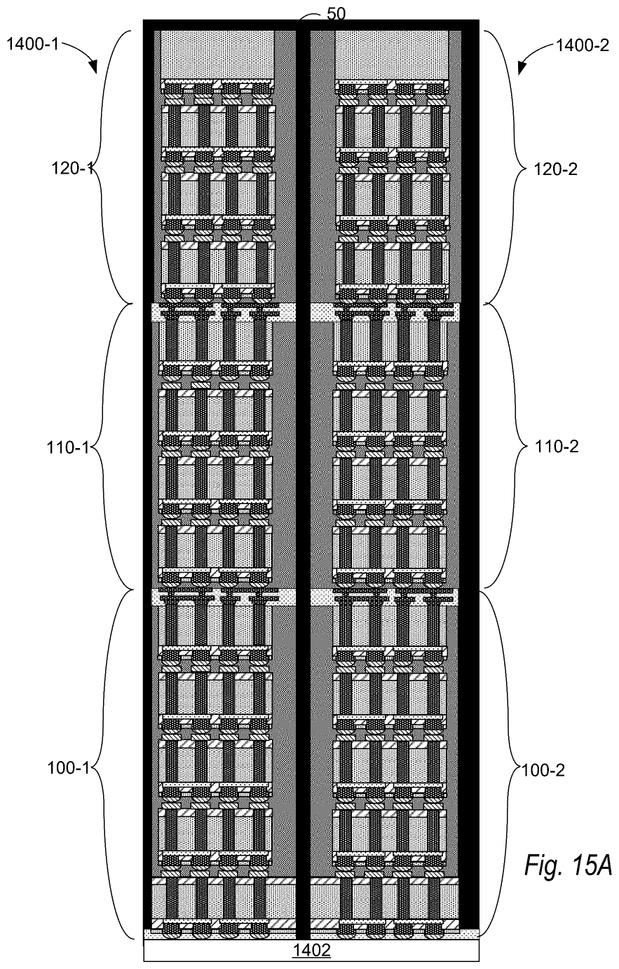

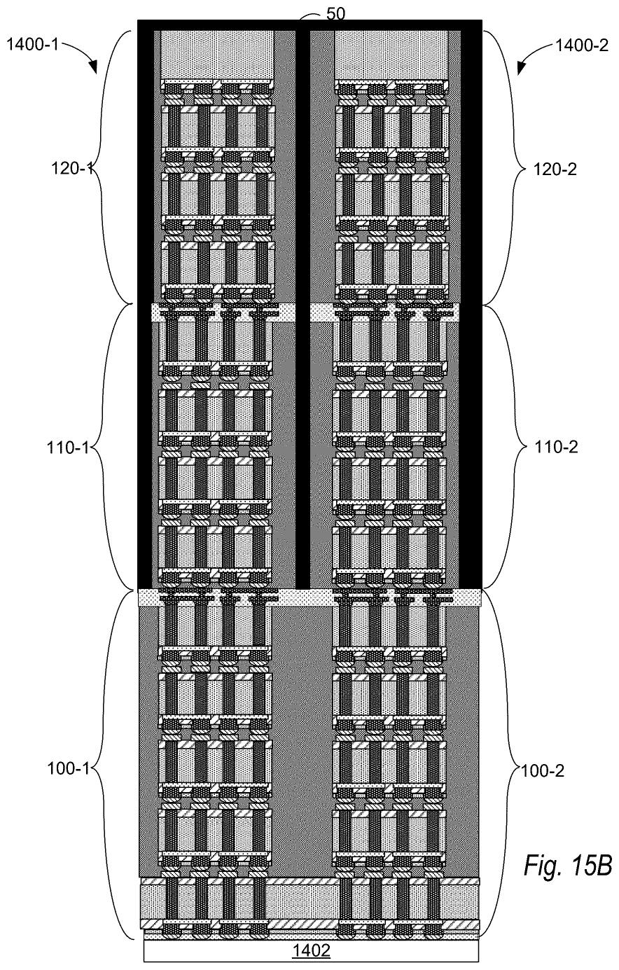

Step 234 includes underfill (optional) and encapsulation (optional). Step 234 may include performing compression molding. In one embodiment, step 234 performs both underfill between the modules and encapsulating sidewalls of modules in a single step. In an embodiment, step 234 includes an L-MUF (Liquid Molded Underfill). Step 234 may include using a MUF material that is suitable for both gap filling (e.g., underfilling between modules) and over molding (e.g., encapsulating sidewalls of modules). Thus, in an embodiment, an L-MUF includes a single step for both underfill and encapsulating sidewalls of modules. In one embodiment, step 234 includes a first step of underfilling between the modules and a second step of encapsulating sidewalls of modules. FIG. 15A depicts results after an embodiment of step 234 in which wafer singulation was performed for all modules. FIG. 15A depicts an example in which a single material is used for both gap filling and over molding. As an example, this material is referred to as a MUF material 50. The MUF material 50 is depicted in small gaps between the adjacent pairs of modules (where RDL meets micropads). The MUF material 50 also surrounds the encapsulate 40 that was previously formed around the dies. FIG. 15B depicts results after an embodiment of step 234 in which the middle modules 110 and top modules 120 underwent wafer singulation, but the wafer singulation was not performed for the bottom modules 100. The MUF material 50 is depicted in small gaps between the adjacent pairs of modules (where RDL meets micropads). The MUF material 50 also surrounds the encapsulant 40 that was previously formed in the middle modules 110 and top modules 120. However, the MUF material 50 is not required for the bottom module 100.

Step 236 includes package singulation. FIG. 1A depicts results after an embodiment of step 236. FIG. 1A depicts a single package 60 that contains a bottom module 100, a middle module 110, and a top module 120. The carrier 1402 and film 1404 have been removed.

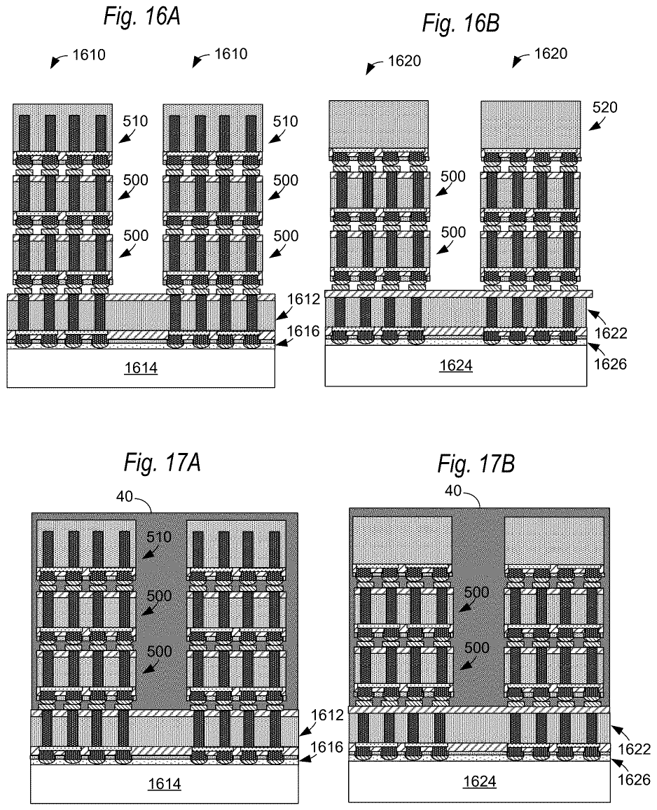

In some embodiments, the vertical stacking of the dies for the middle module 110 and the top module 120 is on a temporary carrier. For example, FIG. 6B depicts an embodiment in which the dies 500, 510 of the middle modules 110 are stacked on a temporary carrier 612. Also, FIG. 6C depicts an embodiment in which the dies 500, 520 of the top modules 120 are stacked on a temporary carrier 622. In an alternative embodiment, the dies of the middle module and the top module are each stacked on core wafers, as opposed to a temporary carrier. FIG. 16A-21B depict alternative embodiments in which the dies of the middle module 110 and the top module 120 are each stacked on core wafers. FIG. 16A-21B will be discussed in connection with various steps of an embodiment of the fabrication process of FIG. 2 in which the dies of the middle module 110 and the top module 120 are each stacked on core wafers. Steps 202 214 are directed to the fabrication of the dies for the bottom modules 100, middle modules 110, and top module 120, which may be similar to the discussion above. Hence, results may be similar to those depicted in FIG. 3A-5C.

As noted above, step 216 includes vertically stacking the memory dies to form modules (as well as die-to-die bonding). The die-to-die bonding could include, for example, thermal compression bonding, tacking and mass reflow, laser assisted bonding, or laser compression bonding. In an embodiment, a bottom module 100, a middle module 110, and a top module 120 are formed. In an embodiment, the bottom module 100 is formed on a base wafer, whereas the middle module 110 and the top module 120 are formed on cores wafers. FIG. 6A, already described above depicts an embodiment of two bottom modules 100 formed on the same base wafer 602. FIG. 16A depicts an embodiment of two stacks 1610, which will become modules 110, formed on a core wafer 1612. The core wafer 1612 has TSVs, metal pads, and microbumps similar to TSV bump/pad die 500. The core wafer 1612 resides on a temporary carrier 1614, with a film 1616 between the core wafer 1612 and temporary carrier 1614. Each stack 1610 has two TSV bump/pad die 500 and an RDL die 510 at the top. FIG. 16B depicts an embodiment of two stacks 1620, which will become top modules 120, formed on a core wafer 1622. The core wafer 1622 has TSVs, metal pads, and microbumps similar to TSV bump/pad die 500. The core wafer 1622 resides on a temporary carrier 1624, with a film 1626 between the core wafer 1622 and temporary carrier 1624. Each top module 1620 has two TSV bump/pad die 500 and a TSV free die 520 at the top.

As noted above, step 218 includes encapsulating the package stacks with a mold compound. FIGS. 17A and 17B correspond to FIGS. 16A and 16B respectively, and depict results after embodiments of step 218. FIG. 17A depicts a mold compound 40 encapsulating the two middle package stacks 1610. FIG. 17B depicts a mold compound 40 encapsulating the two top package stacks 1620. Note that the results for the bottom modules may be similar as depicted in FIG. 7A.

Steps 220-226 involve processing at the top of the modules. Step 220 includes mold wafer grinding. Step 222 includes silicon recess etching for the bottom modules 100 and the middle modules 110. Step 224 includes depositing a dielectric over the exposed TSVs for the bottom modules 100 and the middle modules 110. Step 226 includes a chemical mechanical polish (CMP) and TSV reveal for the bottom modules 100 and the middle modules 110. Given the similarity between the processing in these steps when the modules are stacked on a core wafer to processing when the modules are stacked on a temporary carrier these steps will not be described in detail.

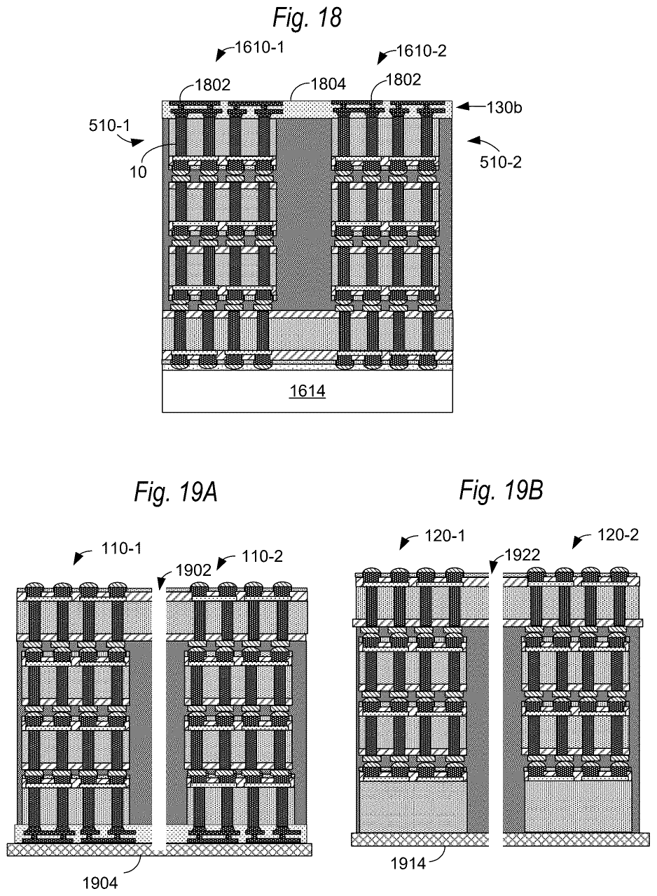

Step 228 includes forming microcontacts that connect to TSVs for the bottom modules 100 and the middle modules 110. In an embodiment, step 228 includes RDL and micropad fabrication for the bottom modules 100 and the middle modules 110. Results after RDL and micropad fabrication for the bottom modules 100 are similar to depicted in FIG. 12A. FIG. 18 depict results after RDL and micropad fabrication for the middle stacks 1610, which will become middle modules 110. FIG. 18 shows an RDL structure 130b having RDL layers within a dielectric material 1804. The top surface of the RDL structure 130b may have micropads 1802 or the like in the dielectric material 1804. The RDL structure 130b has one or more RDL layers such that conductive pathways are formed between the micropads 1802 and the TSVs 10 of the RDL die. The dielectric material 1804 may be formed from one or more layers of dielectric material 1804. One or more types dielectrics may be used for dielectric material 1804.

Step 230 includes molded wafer singulation. In one embodiment, wafer singulation is performed for the bottom modules 100, middle modules 110, and top modules 120. In one embodiment, wafer singulation is performed for the middle modules 110 and top modules 120; however, wafer singulation is not performed for the bottom modules 100. In an embodiment the molded wafer singulation uses a relatively narrow blade width relative to the blade width used in the wafer saw in step 214. The narrow cut in step 230 may be made using a laser (e.g., laser dicing). FIG. 19A corresponds to results after wafer singulation to result in middle modules 110-1, 110-2. FIG. 19A depicts middle modules 110-1, 110-2, which result from the wafer cut 1902. The middle modules 110-1, 110-2 are on a die attach tape 1904. FIG. 19B depicts top modules 120-1, 120-2 which result from the wafer cut 1922. The top modules 120-1, 120-2 are on a die attach tape 1914.

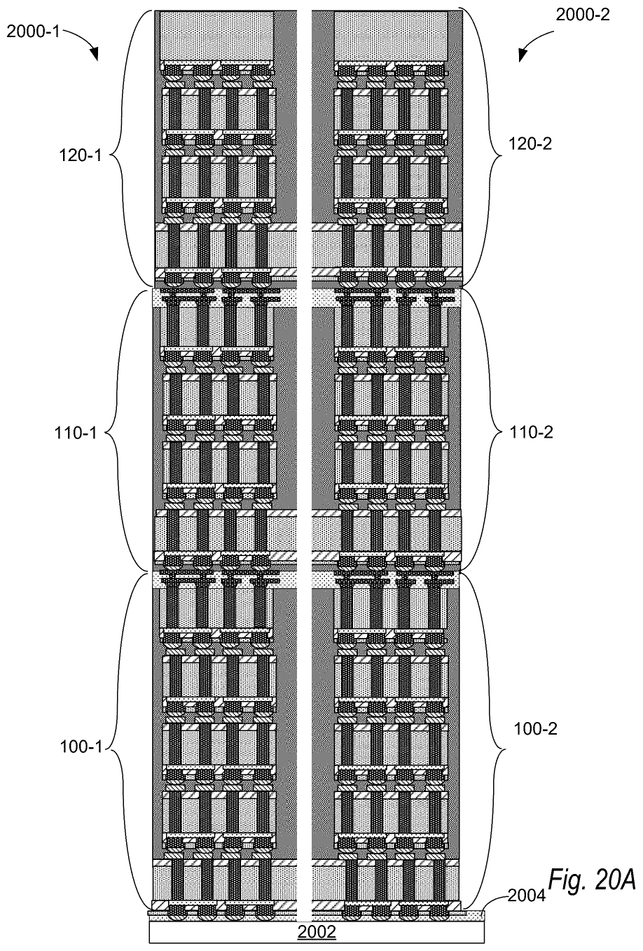

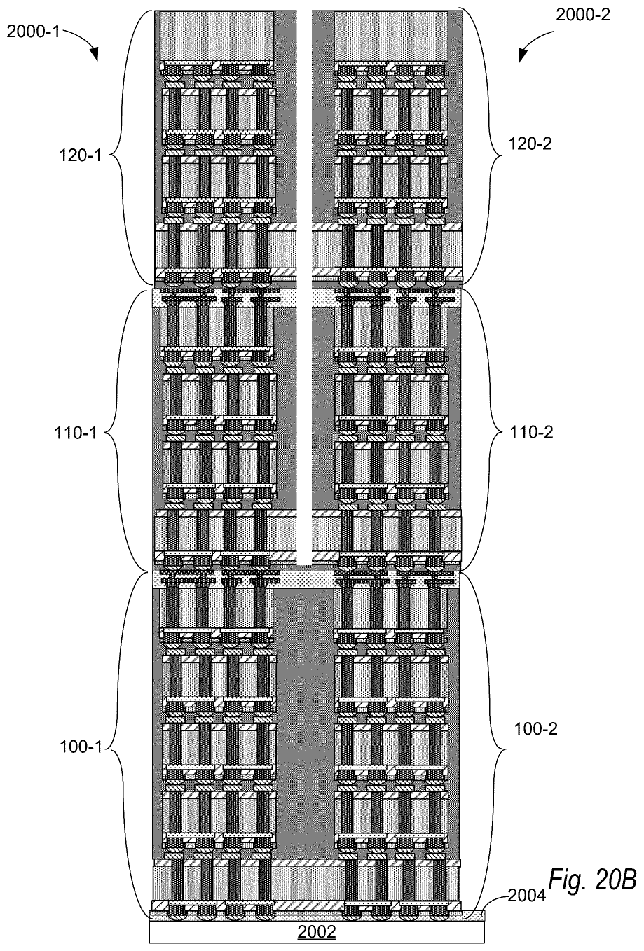

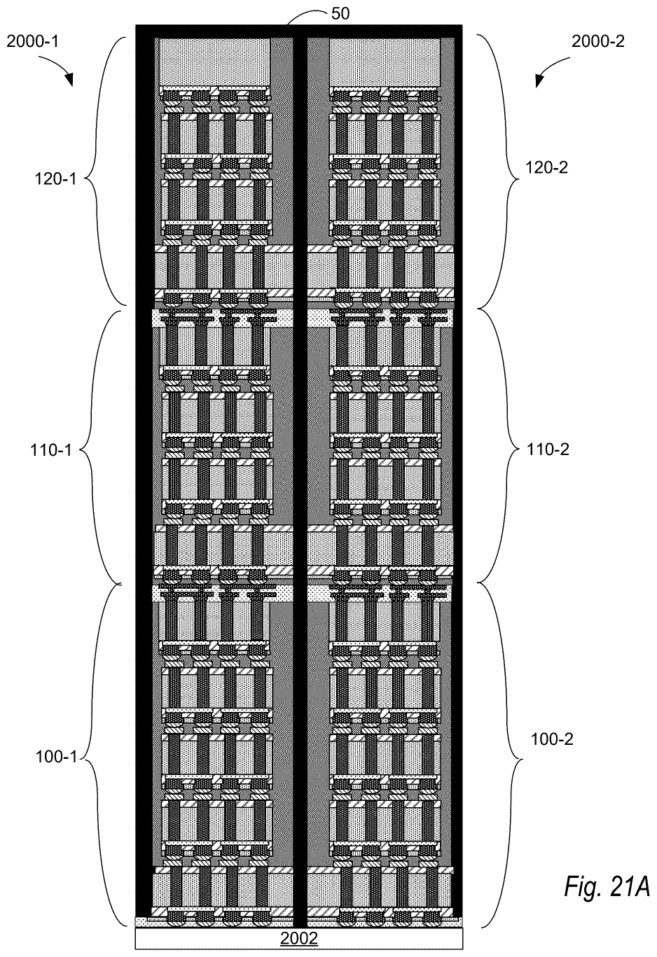

Step 232 includes stacking the modules vertically on a carrier, as well as module-to-module bonding. The module-to-module bonding could include, for example, thermal compression bonding, tacking and mass reflow, laser assisted bonding, or laser compression bonding. In an embodiment, step 232 includes bonding microbumps of one module to micropads of another module. FIG. 20A depicts results after an embodiment of step 232 in which all modules underwent wafer singulation. Bottom module 100-1, middle module 110-1, and top module 120-1 are stacked vertically in a first stack 2000-1 over a carrier 2002, which is attached to the stack by a film 2004. Bottom module 100-2, middle module 110-2, and top module 120-2 are stacked vertically in a second stack 2000-2 over the carrier 2002. FIG. 20B depicts results after an embodiment of step 232 in which the middle modules 110 and top modules 120 underwent wafer singulation, but the wafer singulation was not performed for the bottom modules 100.

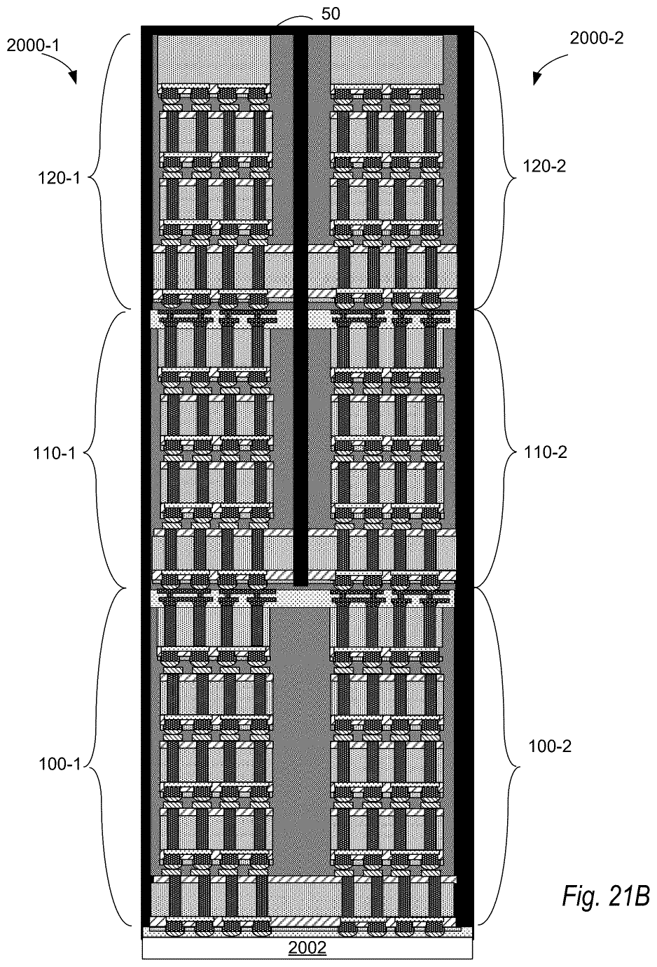

Step 234 includes encapsulating the modules. Step 234 may include performing compression molding. In one embodiment, step 234 performs both underfill and encapsulating sidewalls of modules in a single step. In an embodiment, step 234 includes an L-MUF (Liquid Molded Underfill). Step 234 may include using a MUF material that is suitable for both gap filling and over molding. In one embodiment, step 234 includes a first step of underfilling and a second step of encapsulating sidewalls of modules. FIG. 21A depicts results after an embodiment of step 234 in which wafer singulation was performed for all modules. FIG. 21A depicts an example in which a single material is used for both gap filling and over molding. As an example, this material is referred to as a MUF material 50. The MUF material 50 is depicted in small gaps between the adjacent pairs of modules (where RDL meets micropads). The MUF material 50 also surrounds the encapsulate 40 that was previously formed around the dies. FIG. 21B depicts results after an embodiment of step 234 in which the middle modules 110 and top modules 120 underwent wafer singulation, but the wafer singulation was not performed for the bottom modules 100. The MUF material 50 is depicted in small gaps between the adjacent pairs of modules (where RDL meets micropads). The MUF material 50 also surrounds the encapsulant 40 that was previously formed in the middle modules 110 and top modules 120. However, the MUF material 50 is not required for the bottom module 100.

Step 236 includes package singulation. FIG. 1B depicts results after an embodiment of step 236. FIG. 1B depicts a single package 60 that contains a bottom module 100, a middle module 110, and a top module 120.

Some embodiments include hybrid bonding for the interconnection between the modules in the semiconductor package. Referring back to FIG. 1C, hybrid bonding may be used with CoCoC or CoCoW for the die stack within the modules. Alos, the module stack within the package may be any of: Module on Module on Carrier, Module on Module on Recon Wafer, or Recon Wafer on Recon Wafer. The process of FIG. 2 will now be described with respect to embodiments that include hybrid bonding for the interconnection between the modules in the semiconductor package.

Step 202 includes preparing an incoming wafer for first microcontacts. In an embodiment, an incoming wafer is prepared for hybrid bonding. The incoming wafer may already have through silicon vias (TSV) 10 in semiconductor substates. However, the TSVs are not needed for what is to become the topmost semiconductor die in the top module 120. Step 202 may include forming metal pads on the surface of each semiconductor substate. Step 202 may also include forming a passivation layer on the semiconductor substates to partially cover the metal pads. FIG. 3A shows results after an embodiment of step 202 in which TSVs 10 are formed in the semiconductor substrate 302. FIG. 3A shows results that may be used for all semiconductor dies in the bottom modules 100 and middle modules 110, as well as all semiconductor dies of the top module 120 with the exception of the top semiconductor die. FIG. 3A depicts in incoming wafer 302 with through silicon vias (TSV) 10 in the silicon wafer 302. Metal pads 306 are formed over the TSVs 10. A passivation layer 308a is formed to cover edge portions of metal pads 306. The metal pads 306 may be formed from materials including, but not limited to, aluminum, copper, silver, gold, nickel, tungsten, alloys thereof, and/or multi-layers thereof. The passivation layer 308a may be formed of a dielectric material. FIG. 3B shows results after an embodiment of step 202 in which TSVs are not formed in the semiconductor substrate 302. FIG. 3B shows results that may be used for the topmost semiconductor dies (see die 520 in FIGS. 1A, 1B) in the top module 120. FIG. 3B depicts the metal pads 306 and passivation layer 308.

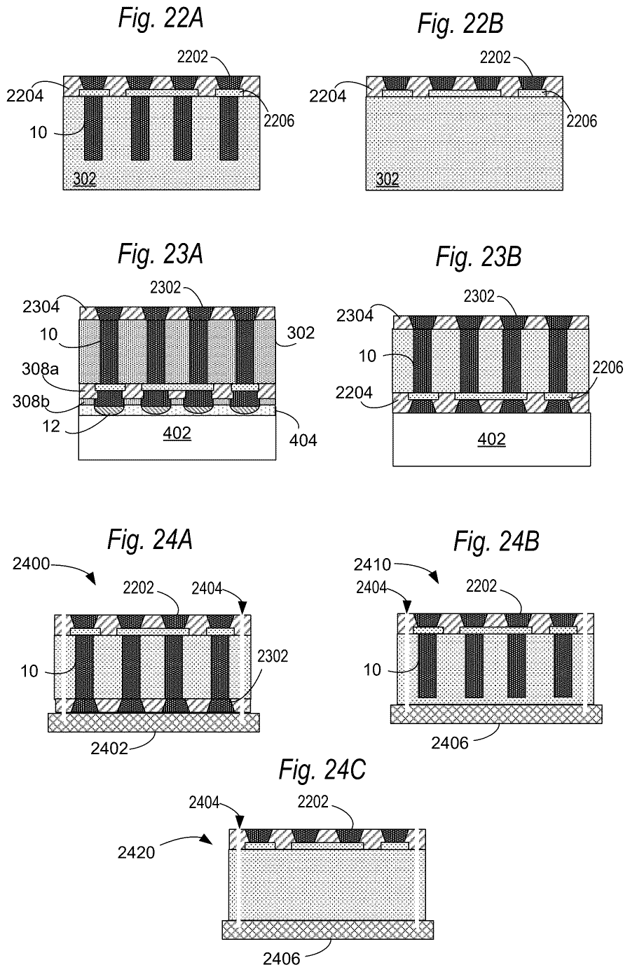

Step 204 includes forming first microcontacts. In an embodiment, step 204 includes copper bonding pad plating for the majority of the dies. However, microbumps may be formed on one of the dies, such that these microbumps will be exposed in the final package. FIG. 3C depicts an example of microbumps 12 formed on a die. FIG. 22A depicts results after an embodiment of step 204 that uses hybrid bonding. The result in FIG. 22A may be used for all but one die in the bottom module 100, all middle modules 110, as well as all semiconductor dies of the top module 120 with the exception of the top semiconductor die. FIG. 22A shows a copper bonding pads 2202 within a dielectric material 2204. Dielectric material 2204 may be organic or inorganic. In one embodiment, the dielectric material 2204 includes SiO2. The copper bonding pads 2202 are formed over metal interconnects 220. The metal interconnects 2206 may be formed from materials including, but not limited to, aluminum, copper, silver, gold, nickel, tungsten, alloys thereof, and/or multi-layers thereof. The depiction of the metal interconnects 2206 is simplified in that there may be multiple layers of metal interconnects that may be formed in, for example, a back end of line (BEOL) process. The side of the die having the metal interconnects 2206 in FIG. 22A may also have devices such as memory cells and transistors (e.g., CMOS), which may be formed in a front end of line process. Not all layers are depicted in FIG. 22A. For example, there may be one or more diffusion barrier layers and one or more seed layers, which are not depicted in the Figures. FIG. 22B shows results after an embodiment of step 204 that may be used for the topmost semiconductor dies in the top module 120. FIG. 22B is similar to FIG. 22A, but lacks the TSVs. The side in which the copper bonding pads 2202 are formed may be referred to as the “device side” of the die.

Step 206 includes temporarily bonding the first microcontacts to a carrier. In an embodiment, a temporary film is formed over a temporary carrier. The temporary film may include an adhesion film over the first microcontacts (e.g., microbumps) and a release film that allows the carrier to easily be removed from the wafer. The temporary film is used to temporarily bond the wafer to the carrier. Step 210 includes revealing the TSVs. Step 212 includes forming second microcontacts on the revealed TSVs. In an embodiment, the second microcontacts include copper micropads, which will be used in hybrid bonding. FIG. 23A depicts results after an embodiment of step 212 for the die in the bottom module 100 that will have its microbumps 12 exposed in the final package. FIG. 23A shows a copper bonding pads 2302 within a dielectric material 2304. Dielectric material 2304 may be organic or inorganic. In one embodiment, the dielectric material 2304 includes SiO2. The copper bonding pads 2302 are attached to the TSVs 10. Not all layers are depicted in FIG. 23A. For example, there may be one or more diffusion barrier layers and one or more seed layers, which are not depicted in the Figures. FIG. 23B shows results after an embodiment of step 212 that may be used for all but the top die in the middle modules 110, all but the top die in the top module 120 and all but the top and bottom dies in the bottom module 100. FIG. 23B shows copper bonding pads 2302 within an organic material 2304. The side in which the TSVs were revealed (having bonding pads 2302) may be referred to as the “silicon side” or the “back side” of the die.

Step 214 includes a core wafer saw. FIG. 24A depicts results after an embodiment of step 214 for all but the top die in the middle module 110, all but the top die in the top module 120 and all but the top and bottom dies in the bottom module 100. FIG. 24A depicts a semiconductor die 2400 with a tape 2402 attached to back (silicon) side of the die 2400 having bonding pads 2302 organic material 2304. Open region 2404 indicates where the core wafer saw has been used to dice the wafer into semiconductor die 2400. Other similar dies 2400 formed in step 214 are not depicted. FIG. 24B depicts results after an embodiment of step 214 the top die 2410 in the bottom module 100 and the middle module 110. FIG. 24B depicts a semiconductor die 2410 with a tape 2406 attached to back (silicon) side of the die 2410. Note that these top dies 2410 have copper pads 220s on the device side but not on the silicon side. FIG. 24C depicts results after an embodiment of step 214 for the top die 2420 in the top module 120. Note that top die 24 does not have TSVs. FIG. 24C depicts a semiconductor die 2420 with a tape 2406 attached to back (silicon) side of the die 2420.

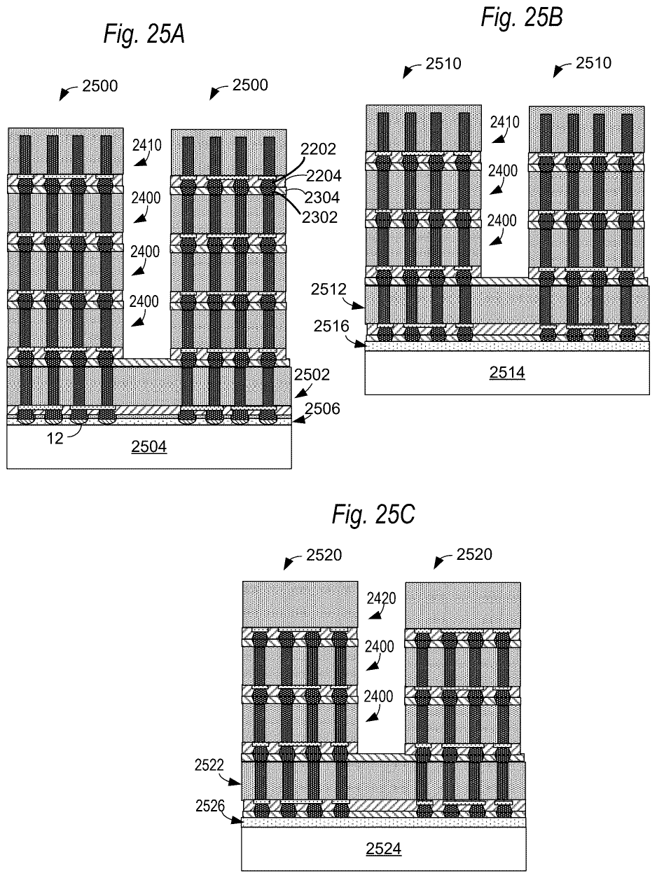

Step 216 includes vertically stacking the memory dies to form modules (as well as die-to-die bonding). The die-to-die bonding could include, for example, thermal compression bonding, low temperature bonding. In an embodiment, the die-to-die bonding includes bonding of the dielectric material 2204 of one die to the dielectric material 2304 an adjacent die, as well as the bonding the copper bonding pads 2202 of one die to the copper bonding pads 2302 of the adjacent die. In an embodiment, a bottom module 100, a middle module 110, and a top module 120 are formed. In an embodiment, the bottom module 100 is formed on a base wafer, whereas the middle module 110 and the top module 120 are formed on core wafers. FIG. 25A depicts an embodiment of two bottom stacks 2500, which will become bottom modules 100, formed on the same base wafer 2502. A temporary film 2506 between a temporary carrier 2504 and the base wafer 2502 protects the microbumps 12 on the base wafer 2502. The dielectric material 2204 of one die is bonded to the dielectric material 2304 of an adjacent die. Also, the copper bonding pads 2202 of one die are bonded to the copper bonding pads 2302 of the adjacent die. Note that the adjacent dies will not necessarily align perfectly, such that there may also be some bonding of the dielectric material (e.g., 2204, 2304) of one die with the copper bonding pads (e.g., 2202, 2302) of the adjacent die.

Each bottom stack 2500 includes one memory die 2410 and three memory dies 2400. FIG. 25B depicts an embodiment of two middle stacks 2510, which will become middle modules 110 formed on the same core wafer 2512. Each middle stack 2510 includes one memory die 2410 and two memory dies 2400 on the same core wafer 2512. A temporary film 2516 between a temporary carrier 2514 and the core wafer 2512 protects the copper bonding pads on the core wafer 2512.

FIG. 25C depicts an embodiment of two top stacks 2520, which will become top modules 120, formed on the same core wafer 2522. Each top stack 2520 includes one memory die 2420 and two memory dies 2400 on the same core wafer 2522. The core wafer 2522 resides on a temporary carrier 2524, with a film 2526 between the core wafer 2522 and temporary carrier 2524.

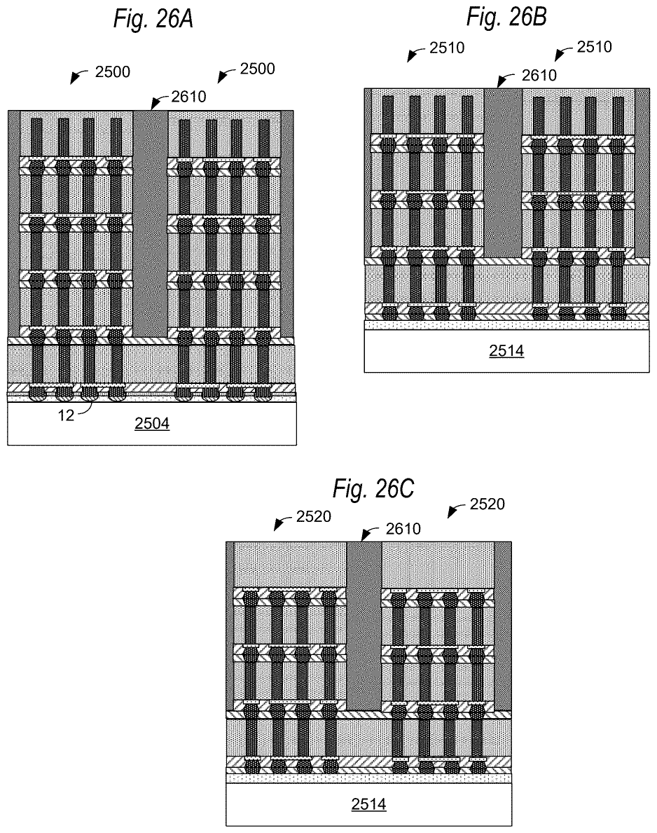

Step 218 includes encapsulating the package stacks with a mold compound. Step 220 includes mold wafer grinding. FIGS. 26A, 26B, and 26C depict results after an embodiment of step 220. FIG. 26A depicts mold compound 2610 encapsulating the bottom stacks 2500. FIG. 26B depicts mold compound 2610 encapsulating the middle stacks 2510. FIG. 26C depicts mold compound 2610 encapsulating the top stacks 2520.

Step 222 includes silicon recess etching for the bottom modules 100 and the middle modules 110. Step 224 includes depositing a dielectric over the exposed TSVs for the bottom modules 100 and the middle modules 110. Step 226 includes a chemical mechanical polish (CMP) and TSV reveal for the bottom modules 100 and the middle modules 110. Given the similarity between the processing in these steps when the interconnection between the modules are microbumps these steps will not be described in detail.

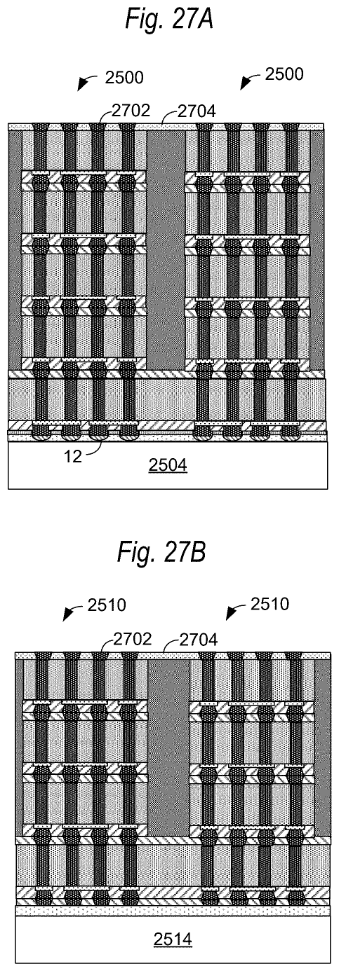

Step 228 includes forming microcontacts connected to the revealed TSVs for the bottom stacks 2500 and the middle stacks 2510. In an embodiment, step 228 includes copper bonding pad plating. FIG. 27A depicts copper bond pads 2702 in a dielectric material 2704 on the bottom stacks 2500. FIG. 27B depicts copper bond pads 2702 in a dielectric material 2704 on the middle stacks 2510.

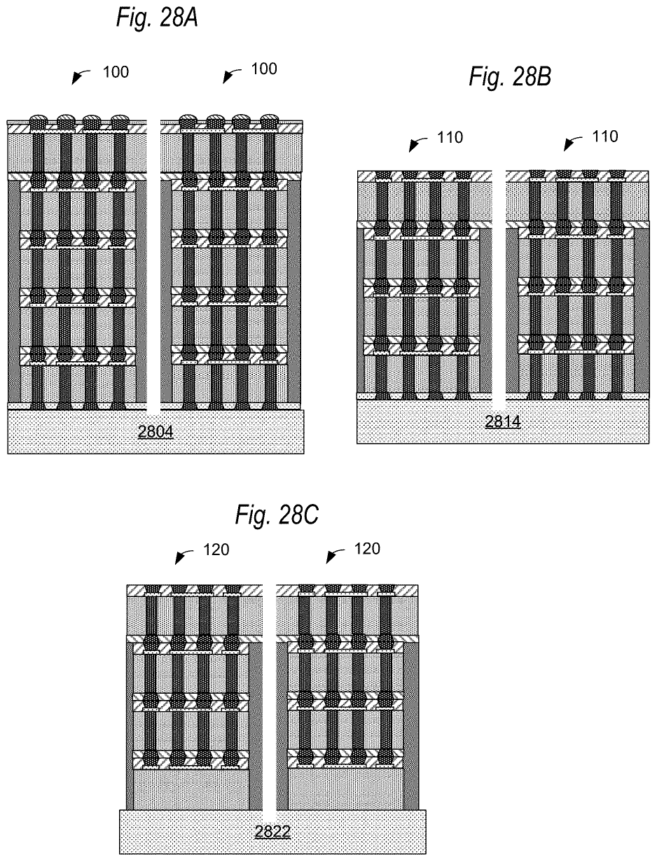

Step 230, which is optional, includes molded wafer singulation. In an embodiment the molded wafer singulation uses a relatively narrow blade width relative to the blade width used in the wafer saw in step 214. The narrow cut in step 230 may be made using a laser (e.g., laser dicing). FIG. 28A corresponds to results after wafer singulation to result in bottom modules 100 on a die attach tape 2804. FIG. 28B corresponds to results after wafer singulation to result in middle modules 110 on a die attach tape 2814. FIG. 28C corresponds to results after wafer singulation to result in top modules 120 on a die attach tape 2822.

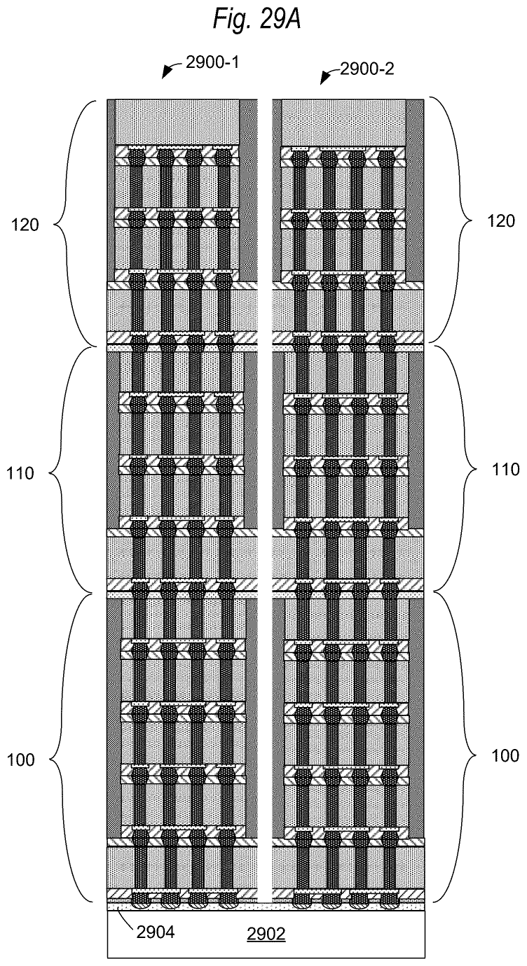

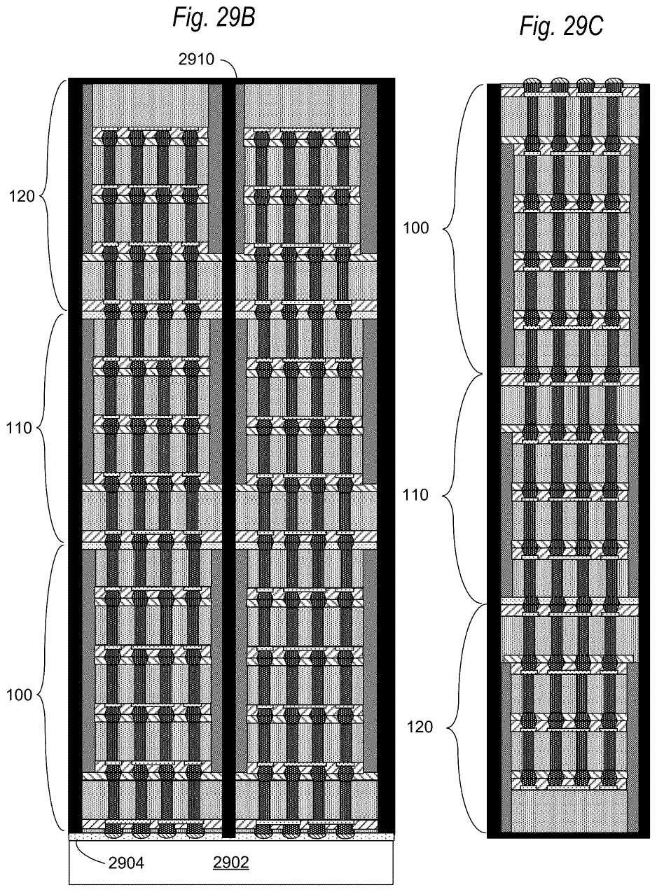

Steps 232-236 will now be discussed for an embodiment in which the package has a module on module on carrier wafer. Step 232 includes stacking the modules vertically on a carrier, as well as module-to-module bonding. In an embodiment, the module-to-module bonding includes bonding of the dielectric material 2204 of one module to the dielectric material 2204 an adjacent module, as well as the bonding the copper bonding pads 2202 of one module to the copper bonding pads 2202 of the adjacent module. The module-to-module bonding could include, for example, thermal compression bonding and low temperature bonding. FIG. 29A depicts results after an embodiment of step 232 in which all modules underwent wafer singulation. Bottom module 100, middle module 110, and top module 120 are stacked vertically in a first stack 2900-1 and a second stack 2900-2 over a carrier 2902, which is attached to the stack by a film 2904. The temporary film 2904 between a temporary carrier 2902 and the stack protects the microbumps. The dielectric material 2204 of a die of one module is bonded to the dielectric material 2304 of a die of an adjacent module. Also, the copper bonding pads 2202 of one die of one module are bonded to the copper bonding pads 2302 of a die of the adjacent module. Note that the dies of the adjacent modules will not necessarily align perfectly, such that there may also be some bonding of the dielectric material (e.g., 2204, 2304) a one die of one module with the copper bonding pads (e.g., 2202, 2302) of a die of the adjacent module.

Step 234 includes encapsulating the modules. Step 234 may include performing compression molding. In an embodiment, step 234 includes an L-MUF (Liquid Molded Underfill). Step 234 may include using a MUF material that is suitable for both gap filling and over molding. FIG. 29B depicts results after an embodiment of step 234 in which wafer singulation was performed for all modules. The MUF material 2910 surrounds the encapsulate that was previously formed around the dies. Step 236 includes package singulation. FIG. 29C depicts results after an embodiment of step 236. FIG. 29C depicts a single package that contains a bottom module 100, a middle module 110, and a top module 120.

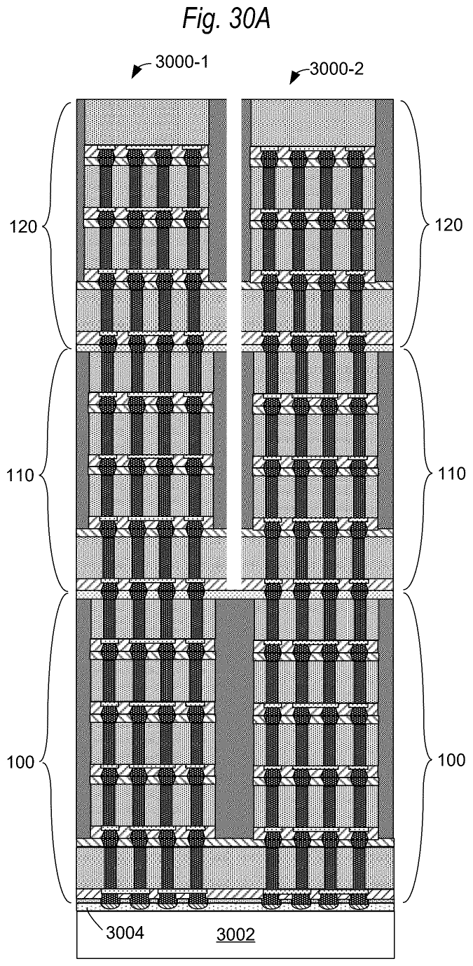

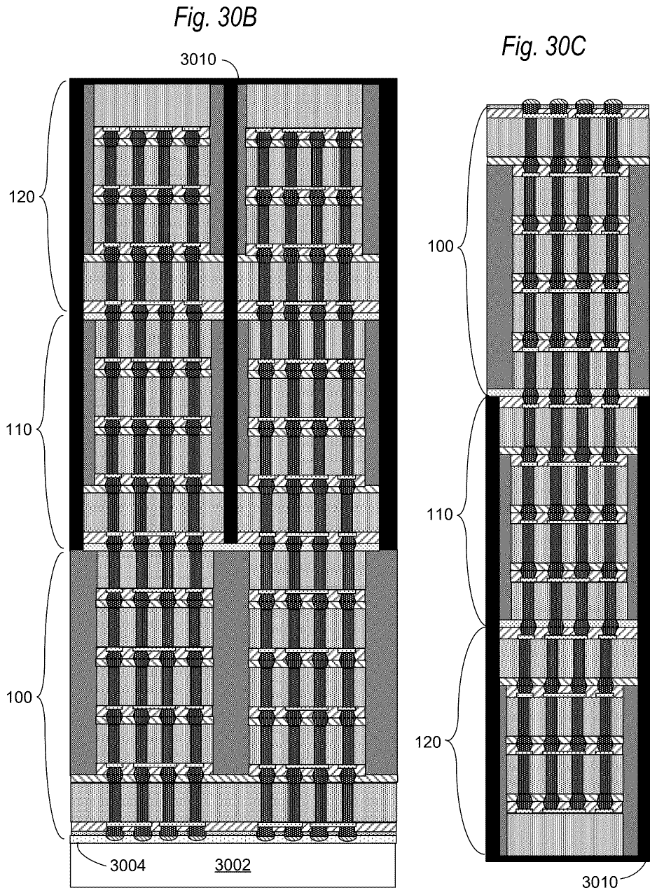

Steps 232-236 will now be discussed for an embodiment in which the package has a module on module on reconstructed wafer. Step 232 includes stacking the modules vertically on a reconstructed wafer, as well as module-to-module bonding. In an embodiment, the module-to-module bonding includes bonding of the dielectric material 2204 of one module to the dielectric material 2204 an adjacent module, as well as the bonding the copper bonding pads 2202 of one module to the copper bonding pads 2202 of the adjacent module. The module-to-module bonding could include, for example, thermal compression bonding, low temperature bonding. FIG. 30A depicts results after an embodiment of step 232 in which the middle modules 110 and top modules 120 underwent wafer singulation. Middle modules 110 and top modules 120 are stacked vertically over a reconstructed wafer, which is attached to a temporary carrier 3002 by a film 3004. Step 234 includes encapsulating the modules. The dielectric material 2204 of a die of one module is bonded to the dielectric material 2304 of a die of an adjacent module. Also, the copper bonding pads 2202 of one die of one module are bonded to the copper bonding pads 2302 of a die of the adjacent module. Note that the dies of the adjacent modules will not necessarily align perfectly, such that there may also be some bonding of the dielectric material (e.g., 2204, 2304) a one die of one module with the copper bonding pads (e.g., 2202, 2302) of a die of the adjacent module. Step 234 may include performing compression molding. In an embodiment, step 234 includes an L-MUF (Liquid Molded Underfill). Step 234 may include using a MUF material that is suitable for both gap filling and over molding. FIG. 30B depicts results after an embodiment of step 234 in which wafer singulation was performed for all modules. The MUF material 3010 surrounds the encapsulate that was previously formed around the dies. Step 236 includes package singulation. FIG. 30C depicts results after an embodiment of step 236. FIG. 29C depicts a single package that contains a bottom module 100, a middle module 110, and a top module 120.

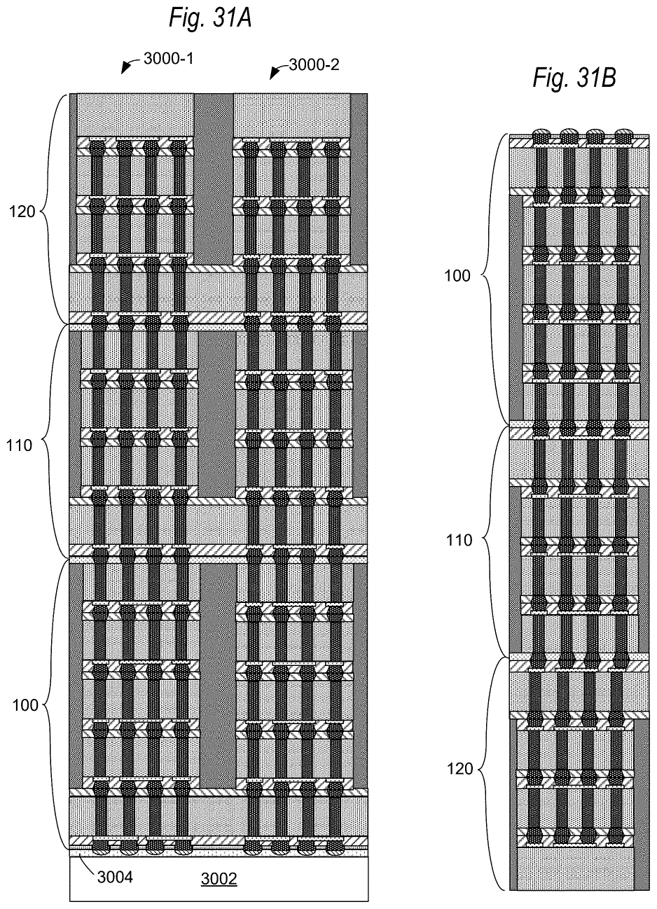

Steps 232 and 236 will now be discussed for an embodiment in which the package has a reconstructed wafer on reconstructed wafer. Step 232 includes stacking the modules vertically, as well as module-to-module bonding. In an embodiment, the module-to-module bonding includes bonding of the dielectric material 2204 of one module to the dielectric material 2204 an adjacent module, as well as the bonding the copper bonding pads 2202 of one module to the copper bonding pads 2202 of the adjacent module. The module-to-module bonding could include, for example, thermal compression bonding or low temperature bonding. Step 234 (encapsulating the modules) is not required. Step 236 includes package singulation. FIG. 31A depicts results after an embodiment of step 236. The dielectric material 2204 of a die of one module is bonded to the dielectric material 2304 of a die of an adjacent module. Also, the copper bonding pads 2202 of one die of one module are bonded to the copper bonding pads 2302 of a die of the adjacent module. Note that the dies of the adjacent modules will not necessarily align perfectly, such that there may also be some bonding of the dielectric material (e.g., 2204, 2304) a one die of one module with the copper bonding pads (e.g., 2202, 2302) of a die of the adjacent module. FIG. 31B depicts a single package that contains a bottom module 100, a middle module 110, and a top module 120.

In summary, in one example, the present technology relates to a method comprising forming n modules with each module comprising a stack of dies, wherein n is an integer of at least two, wherein at least a first subset of the dies in each of the n modules has through silicon vias (TSV) therein. At least a second subset of the dies in each of the n modules are memory dies comprises memory cells. Forming the n modules includes forming first microcontacts conductively connected to the TSVs of a first die of each of the n modules. Forming the n modules includes stacking the dies for each module with the first die on a first side of the stack. Forming the n modules includes revealing the TSVs of a second die in the stack for each of n-1 of the modules, the second die on a second side of the stack that is opposite the first side of the stack. Forming the n modules includes forming second microcontacts conductively connected to the revealed TSVs of the second die of each of the n-1 modules. The method further includes stacking the n modules with the second microcontacts of the second die of each of the n-1 modules aligned with the first microcontacts of the first die of an adjacent module of the n modules. The method further includes bonding the first microcontacts that are aligned with the second microcontacts.

In a further aspect stacking the dies for each module with the first die on a first side of the stack comprises for a first module of the n modules includes stacking the dies of the first module on a temporary carrier with a temporary film covering the first microcontacts of the first die of the first module.

In a further aspect, the first microcontacts comprise microbumps and the second microcontacts comprise micropads.

In a further aspect, forming the first microcontacts conductively connected to the TSVs of the first die of each of the n modules comprises forming microbumps conductively connected to the TSVs of the first die through conductive pathways. And forming the second microcontacts conductively connected to the TSVs of the second die of each of the n-1 modules comprises forming micropads conductively connected to the TSVs of the second die through conductive pathways.

In a further aspect, forming the second microcontacts conductively connected to the revealed TSVs of the second die of a particular module of each of the n-1 modules includes: forming a redistribution structure on the second side of the particular module, including forming the second microcontacts in a dielectric material of the redistribution structure and forming conductive pathways in the dielectric material connecting the TSVs of the second die of the particular module to corresponding ones of the second microcontacts.

In a further aspect, bonding the first microcontacts that are aligned with the second microcontacts comprises copper-copper hybrid bonding of first copper micropads to second copper micropads.

In a further aspect, forming the first microcontacts conductively connected to the TSVs of the first die of each of the n modules comprises plating first copper micropads conductively connected to the TSVs of the first die. And forming the second microcontacts conductively connected to the TSVs of the second die of each of the n-1 modules comprises plating second copper micropads conductively connected to the TSVs of the second die.

In a further aspect, forming the n modules comprises, for each particular module of the n modules, encapsulating the stack of dies of the particular module with a mold compound. Revealing the TSVs of the second die, for each particular module of the n-1 modules, comprises: removing the mold compound adjacent to the second die; and etching a silicon substrate of the second die in which the TSVs reside to reveal the TSVs.

In a further aspect, the method further comprises encapsulating the n modules with a mold compound thereby forming a semiconductor package with the first microcontacts of a module of the n modules at an end of the stack exposed.

In a further aspect, the method further comprises performing an underfill of a gap between adjacent modules in the stack of n modules and encapsulating sidewalls of the modules in a single step.

In a further aspect, performing the underfill of the gap between adjacent modules in the stack of n modules and encapsulating sidewalls of the modules in the single step comprises performing an L-MUF (Liquid Molded Underfill).

In a further aspect, the method further comprises performing an underfill of a gap between adjacent modules in the stack of n modules in a first step, and encapsulating sidewalls of the modules in a second step.

In a further aspect, stacking the n modules with the second microcontacts of the second die of each of the n-1 modules aligned with the first microcontacts of the first die of an adjacent module of the n modules comprises stacking the n modules in a singulated structure on a temporary carrier.

In a further aspect, the n modules comprise a bottom module and stacking the n modules with the second microcontacts of the second memory die of each of the n-1 modules aligned with the first microcontacts of the first memory die of an adjacent module of the n modules comprises stacking all but the bottom module of the n modules on a reconstructed wafer that contains a plurality of bottom modules. And further comprising singulating the reconstructed wafer after bonding the first microcontacts that are aligned with the second microcontacts.

In a further aspect the n modules comprise a bottom module, a middle module, and a top module. Stacking the n modules with the second microcontacts of the second die of each of the n-1 modules aligned with the first microcontacts of the first die of an adjacent module of the n modules comprises stacking n reconstructed wafers that each contain modules. Each reconstructed wafer comprises a plurality of bottom modules, a plurality of middle modules, and a plurality of top modules. And further comprising singulating the n reconstructed wafers after bonding the first microcontacts that are aligned with the second microcontacts.

In a further aspect, the n modules comprise a bottom module and at least one additional module. Forming the n modules comprises for all but the bottom module of the n modules: stacking the dies of the module on a temporary carrier and bonding the stack of the dies together.

In a further aspect, forming the n modules for each particular module of the n modules comprises stacking a subset of the dies of the particular module on core wafer and cutting the core wafer to result in an additional die for the first module.

An embodiment includes a semiconductor package, comprising n modules in a stack, wherein each module comprises a plurality of dies stacked vertically. The dies comprise through silicon vias (TSV) to route signals through the stack, wherein n-1 of the modules comprise a redistribution structure having micropads. The micropads of the redistribution structure of a particular module are bonded to microbumps of an adjacent module in the stack to form signal pathways between the TSVs of the particular module and the adjacent module. The semiconductor package has an encapsulant surrounding the n modules with microbumps associated with the TSVs on a bottom die of a bottom module of the stack exposed on a surface of the encapsulant.

An embodiment includes a method for fabricating a semiconductor package. The method comprises forming a plurality of modules. Each module having a vertical stack of memory dies. Each particular module having microbumps on a bottom surface of the particular module that are connected to corresponding TSVs of a bottom memory die of the particular module. The method comprises forming a redistribution (RDL) structure on a top surface of all but one module of the plurality of modules, including: forming electrical pathways in a dielectric material of the RDL structure of a particular module that connect to the TSVs in a top memory die of the particular module; and forming micropads in a top surface of the dielectric material of the RDL structure. The micropads are electrically connected to the electrical pathways in the RDL structure of the particular module to thereby connect the micropads to corresponding TSVs in the top memory die of the particular module. The method comprises forming a vertical stack of the plurality of modules, including bonding the micropads of each respective RDL structure to the microbumps of an adjacent module in the vertical stack thereby forming signal pathways between corresponding TSVs of the bottom memory die of the module having the respective RDL structure and the top memory die of the adjacent module. The method comprises encapsulating the vertical stack of the plurality of modules with a mold compound.

An embodiment includes a method for fabricating a semiconductor package, the method comprising forming a plurality of modules. The plurality of modules comprising a bottom module, a top module and one or more middle modules. Each module has a vertical stack of memory dies. At least a subset of the memory dies having through silicon vias (TSVs), forming the bottom module comprises forming micropads on a memory die on a top side of the bottom module that are connected to corresponding TSVs of the memory die on the top side of the bottom module. Forming the one or more middle modules comprises, for each middle module, forming micropads on a memory die on a top side of the middle module that are connected to corresponding TSVs of the memory die on the top side of the middle module and forming micropads on a memory die on a bottom side of the middle module that are connected to corresponding TSVs of the memory die on the bottom side of the middle module. Forming the top module comprises forming micropads on a memory die on a bottom side of the top module that are connected to corresponding TSVs of the memory die on the bottom side of the top module. Forming a vertical stack of the plurality of modules with the one or more middle modules between the top module and the bottom module, including hybrid bonding the microrads of adjacent modules in the vertical stack to each other thereby forming signal pathways between the TSVs of the memory dies.

The foregoing detailed description of the technology has been presented for purposes of illustration and description. It is not intended to be exhaustive or to limit the technology to the precise form disclosed. Many modifications and variations are possible in light of the above teaching. The described embodiments were chosen in order to best explain the principles of the technology and its practical application to thereby enable others skilled in the art to best utilize the technology in various embodiments and with various modifications as are suited to the particular use contemplated. It is intended that the scope of the technology be defined by the claims appended hereto.

We claim:

1. A method comprising:
forming n modules with each module comprising a stack of dies, wherein n is an integer of at least two, wherein at least a first subset of the dies in each of the n modules has through silicon vias (TSV) therein, wherein at least a second subset of the dies in each of the n modules are memory dies comprising memory cells, including:
forming first microcontacts conductively connected to the TSVs of a first die of each of the n modules;
stacking the dies for each module with the first die on a first side of the stack;
revealing the TSVs of a second die in the stack for each of n-1 of the modules, the second die on a second side of the stack that is opposite the first side of the stack; and
forming second microcontacts conductively connected to the revealed TSVs of the second die of each of the n-1 modules;
stacking the n modules with the second microcontacts of the memory die of each of the n-1 modules aligned with the first microcontacts of the first die of an adjacent module of the n modules; and
bonding the first microcontacts that are aligned with the second microcontacts.

2. The method of claim 1, wherein stacking the dies for each module with the first die on a first side of the stack comprises for a first module of the n modules includes:
stacking the dies of the first module on a temporary carrier with a temporary film covering the first microcontacts of the first die of the first module.

3. The method of claim 1, wherein:
forming the n modules comprises, for each particular module of the n modules, encapsulating the stack of dies of the particular module with a mold compound; and
revealing the TSVs of the second die, for each particular module of the n-1 modules, comprises:
removing the mold compound adjacent to the second die; and
etching a silicon substrate of the second die in which the TSVs reside to reveal the TSVs.

4. The method of claim 1, wherein:
forming the first microcontacts conductively connected to the TSVs of the first die of each of the n modules comprises forming microbumps conductively connected to the TSVs of the first die through conductive pathways; and
forming the second microcontacts conductively connected to the TSVs of the second die of each of the n-1 modules comprises forming micropads conductively connected to the TSVs of the second die through conductive pathways.

5. The method of claim 1, wherein forming the second microcontacts conductively connected to the revealed TSVs of the second die of a particular module of each of the n-1 modules includes:
forming a redistribution structure on the second side of the particular module, including forming the second microcontacts in a dielectric material of the redistribution structure and forming conductive pathways in the dielectric material connecting the TSVs of the second die of the particular module to corresponding ones of the second microcontacts.

6. The method of claim 1, wherein bonding the first microcontacts that are aligned with the second microcontacts comprises performing copper-copper hybrid bonding of first copper micropads to second copper micropads.

7. The method of claim 1, wherein:
forming the first microcontacts conductively connected to the TSVs of the first die of each of the n modules comprises plating first copper micropads conductively connected to the TSVs of the first die; and
forming the second microcontacts conductively connected to the TSVs of the second die of each of the n-1 modules comprises plating second copper micropads conductively connected to the TSVs of the second die.

8. The method of claim 1, further comprising:
encapsulating the n modules with a mold compound thereby forming a semiconductor package with the first microcontacts of a module of the n modules at an end of the stack exposed.

9. The method of claim 1, further comprising:
performing an underfill of a gap between adjacent modules in the stack of n modules and encapsulating sidewalls of the modules in a single step.

10. The method of claim 1, further comprising:
performing an underfill of a gap between adjacent modules in the stack of n modules in a first step; and
encapsulating sidewalls of the modules in a second step.

11. The method of claim 1, wherein stacking the n modules with the second microcontacts of the second die of each of the n-1 modules aligned with the first microcontacts of the first die of an adjacent module of the n modules comprises:
stacking the n modules in a singulated structure on a temporary carrier.

12. The method of claim 1, wherein the n modules comprise a bottom module and stacking the n modules with the second microcontacts of the second memory die of each of the n-1 modules aligned with the first microcontacts of the first memory die of an adjacent module of the n modules comprises:
stacking all but the bottom module of the n modules on a reconstructed wafer that contains a plurality of bottom modules; and further comprising singulating the reconstructed wafer after bonding the first microcontacts that are aligned with the second microcontacts.

13. The method of claim 1, wherein:
the n modules comprise a bottom module, a middle module, and a top module, and stacking the n modules with the second microcontacts of the second die of each of the n-1 modules aligned with the first microcontacts of the first die of an adjacent module of the n modules comprises:
stacking n reconstructed wafers that each contain modules, each reconstructed wafer comprising a plurality of bottom modules, a plurality of middle modules, and a plurality of top modules; and further comprising singulating the n reconstructed wafers after bonding the first microcontacts that are aligned with the second microcontacts.

14. The method of claim 1, wherein the n modules comprise a bottom module and at least one additional module, and forming the n modules comprises for all but the bottom module of the n modules:
stacking the dies of the module on a temporary carrier; and
bonding the stack of the dies together.

15. The method of claim 1, wherein forming the n modules comprises for each particular module of the n modules:
stacking a subset of the dies of the particular module on a core wafer; and
cutting the core wafer to result in an additional die for the particular module.

16. A method for fabricating a semiconductor package, the method comprising:
forming a plurality of modules, each module having a vertical stack of memory dies, each particular module having microbumps on a bottom surface of the particular module that are connected to corresponding TSVs of a bottom memory die of the particular module;
forming a redistribution (RDL) structure on a top surface of all but one module of the plurality of modules, including:
forming electrical pathways in a dielectric material of the RDL structure of a particular module that connect to the TSVs in a top memory die of the particular module; and
forming micropads in a top surface of the dielectric material of the RDL structure, wherein the micropads are electrically connected to the electrical pathways in the RDL structure of the particular module to thereby connect the micropads to corresponding TSVs in the top memory die of the particular module;
forming a vertical stack of the plurality of modules, including bonding the micropads of each respective RDL structure to the microbumps of an adjacent module in the vertical stack thereby forming signal pathways between corresponding TSVs of the bottom memory die of the module having the respective RDL structure and the top memory die of the adjacent module; and
encapsulating the vertical stack of the plurality of modules with a mold compound.

17. The method of claim 16, further comprising:
performing an underfill of a gap between adjacent modules in the vertical stack of plurality of modules and encapsulating sidewalls of the modules in a single step.

18. The method of claim 17, encapsulating the vertical stack of the plurality of modules with the mold compound comprises:
performing an L-MUF (Liquid Molded Underfill).

19. A method for fabricating a semiconductor package, the method comprising:
forming a plurality of modules, the plurality of modules comprising a bottom module, a top module and one or more middle modules, each module having a vertical stack of memory dies, at least a subset of the memory dies having through silicon vias (TSVs), wherein:
forming the bottom module comprises forming micropads on a memory die on a top side of the bottom module that are connected to corresponding TSVs of the memory die on the top side of the bottom module;
forming the one or more middle modules comprises, for each middle module, forming micropads on a memory die on a top side of the middle module that are connected to corresponding TSVs of the memory die on the top side of the middle module and forming micropads on a memory die on a bottom side of the middle module that are connected to corresponding TSVs of the memory die on the bottom side of the middle module; and
forming the top module comprises forming micropads on a memory die on a bottom side of the top module that are connected to corresponding TSVs of the memory die on the bottom side of the top module; and
forming a vertical stack of the plurality of modules with the one or more middle modules between the top module and the bottom module, including hybrid bonding the micropads of adjacent modules in the vertical stack to each other thereby forming signal pathways between the TSVs of the memory dies.

20. The method of claim 19, wherein hybrid bonding the micropads of adjacent modules in the vertical stack to each other includes:
forming dielectric to dielectric bonds; and
forming copper micropad to copper micropad bonds.
